(19) United States
(12) Patent Application Publication
(10) Pub. No.: US 2026/0365890 A1
(43) Pub. Date: Nov. 19, 2026

(54) SOLUTION PROCESSABLE ULTRA-THIN SUBSTRATES AND RELATED TECHNIQUES

(71) Applicant: Massachusetts Institute of Technology, Cambridge, MA (US)

(72) Inventors: Vladimir Bulovic, Lexington, MA (US); Mayuran Saravanapavanantham, Cupertino, CA (US); Jeremiah Mwaura, Andover, MA (US)

(73) Assignee: Massachusetts Institute of Technology, Cambridge, MA (US)

(21) Appl. No.: 19/133,496

(22) PCT Filed: Nov. 28, 2023
(86) PCT No.: PCT/US2023/081244

§ 371 Date: May 28, 2025

Related U.S. Application Data
(63) Continuation-in-part of application No. 17/938,180, filed on Oct. 5, 2022, now Pat. No. 11,935,977.
(60) Provisional application No. 63/252,974, filed on Oct. 6, 2021.
(60) Provisional application No. 63/385,092, filed on Nov. 28, 2022.

(51) Int. Cl. C09J 7/40; C09J 5/00; C09J 7/38; H10F 19/31; H10F 71/10

(52) U.S. Cl. CPC C09J 7/405; C09J 5/00; C09J 7/38; H10F 19/31; H10F 71/107; C09J 2203/322; C09J 2400/266; C09J 2467/00; C09J 2483/005

(57) ABSTRACT

Described are concepts, systems, methods, and machines for providing a device (e.g., electronic device) on a transferable, ultra-thin substrate. The described concepts, systems, methods, and machines may be used to produce an electronic device on a transferable, ultra-thin substrate using only solution-based (e.g., wet) processing techniques. The described concepts systems, methods, and machines may also be used to produce a releasable substrate for the electronic device having a certain desired characteristic. Structures including a device are also described. The structures may include the device, a releasable substrate, and a removable release liner carrier. Also described are systems, methods, and machines for removing a release liner carrier from a releasable substrate and device, for applying the releasable substrate and device to a permanent substrate, and for reusing the release liner carrier to produce another device.

### CROSS REFERENCE TO RELATED APPLICATIONS

This application claims the benefit of U.S. Provisional Application No. 63/385,092, filed on Nov. 28, 2022, which is hereby incorporated herein by reference in its entirety. This application also claims the benefit of U.S. application Ser. No. 17/938,180, filed on Oct. 5, 2022, and U.S. Provisional Application No. 63/252,974, filed on Oct. 6, 2021, both of which are incorporated herein by reference in their entirety.

### BACKGROUND

### 1. Technical Field

The present disclosure relates to techniques for producing and using transferable ultra-thin substrates. More particularly, and without limitation, the present disclosure relates to systems, machines, and methods for producing devices on transferable ultra-thin substrates in a manner that is fast and scalable. Structures including a device and a transferable ultra-thin substrate are also provided. The present disclosure further relates to use of structures that include ultra-thin substrates and devices.

### 2. Background

Ultra-thin semiconductor devices (e.g., ultra-thin photovoltaic (PV) devices) can be prepared on premade substrates such as plastic films and metal foils, or on in-situ formed substrates such as chemical vapor deposited parylene or solution-processed polyimide. Owing to their extremely thin forms and mechanical fragility, these devices are prepared on carrier substrates and may be delaminated upon completion of the device fabrication process. The presence of surface defects and thickness variation on premade ultra-thin substrates, along with challenges associated with handling such ultra-thin substrates prior to lamination onto a carrier have led to in-situ deposited substrates being more commonly used.

With the use of an additional encapsulation layer on top of a completed device, the overall geometries allow functional components of the device to be located in a “neutral plane,”—i.e., a plane which reduces or limits mechanical-stress-damage to the device when flexed. Furthermore, device lamination onto pre-stretched elastomers allows for the formation of buckling structures which then show exceptional resilience under mechanical flexing and compression tests. In addition to PVs, there have been reports of a wide array of electronic and optoelectronic devices prepared in a similar fashion.

### SUMMARY

Embodiments of the present disclosure relate to systems, methods, and machines for creating a device (e.g., electronic device) on a transferable, ultra-thin substrate. The systems, methods, and machines may be used to produce an electronic device on a transferable, ultra-thin substrate using only solution-based (e.g., wet) processing techniques. The systems, methods, and machines may also be used to produce a releasable substrate having a certain desired characteristic. Embodiments of the present disclosure also relate to structures including devices. A structure may include a device, a releasable substrate, and a removable release liner carrier. Embodiments of the present disclosure also relate to systems, methods, and machines for removing a release liner carrier from a releasable substrate and device, for applying the releasable substrate and device to a permanent substrate, and for reusing the release liner carrier to produce another device.

In accordance with certain embodiments of the present disclosure, systems and methods are provided that form a releasable substrate on a release liner carrier by applying a solution to the release liner carrier, and that form an electronic device over the releasable substrate to produce a transferable electronic device.

The systems and methods may also include using a solution that includes a soluble resin. The systems and methods may further include using a solution that includes a soluble resin that is a polyester. The systems and methods may additionally include using a release liner carrier that includes a silicone coating. The systems and methods may also include identifying a characteristic for the releasable substrate, choosing a solution based on the identified characteristic, and applying the chosen solution to the release liner carrier to create a releasable substrate having the identified characteristic. The systems and methods may further include that the desired characteristic is an ultraviolet light filtering characteristic, and may further determine a concentration of an ultraviolet light filtering dye to include in the solution based on the ultraviolet light filtering characteristic, choose a solution that includes the determined concentration of the ultraviolet light filtering dye, and apply the chosen solution to form the releasable substrate having the ultraviolet light filtering characteristic. The systems and methods may additionally include that the desired characteristic is a thickness characteristic, and may further determine a concentration of a soluble resin to include in the solution based on the thickness characteristic, chose a solution that includes the determined concentration of the soluble resin, and apply the chosen solution to form the releasable substrate having the thickness characteristic. The systems and methods may also form the electronic device by forming a first functional layer of the electronic device by coating or printing a first solution on the releasable substrate, and forming a second functional layer of the electronic device by coating or printing a second solution on the first functional layer.

In accordance with some embodiments, there is provided a structure including an electronic device. The structure comprises a silicone-coated release liner carrier, a releasable substrate comprising a resin and formed over the silicone-coated release liner carrier, and an electronic device that is formed over the releasable substrate.

The structure may also include a releasable substrate that is a polyester. The structure may further include a release liner carrier that is configured to be removed from the releasable substrate without damaging the releasable substrate or the electronic device. The structure may additionally include an electronic device that is a photovoltaic device. The structure may also include an electronic device that is composed of at least a first functional layer and a second functional layer, the first functional layer being attached to the releasable substrate. The structure may further include that the releasable substrate has an ultraviolet filtering, moisture barrier, scratch resistant, anti-reflectance, or thickness characteristic. The structure may additionally include that the silicone-coated release liner carrier is flexible.

Furthermore, in accordance with some embodiments, there is provided a method that includes removing a silicone-coated release liner carrier from a releasable substrate comprising a resin, wherein the releasable substrate is attached to an electronic device, and applying the releasable substrate and electronic device to a permanent substrate.

The method may also include reusing the silicone-coated release liner carrier to form another electronic device. The method may further include that the permanent substrate is a fabric. The method may additionally include that the releasable substrate is formed of a polyester. The method may also include operating the electronic device on the permanent substrate.

Before explaining example embodiments consistent with the present disclosure in detail, it is to be understood that the disclosure is not limited in its application to the details of constructions and to the arrangements set forth in the following description or illustrated in the drawings. The disclosure is capable of being practiced and carried out in various ways. Also, it is to be understood that the phraseology and terminology employed herein, as well as in the abstract, are for the purpose of description and should not be regarded as limiting.

It is to be understood that both the foregoing general description and the following detailed description are explanatory only and are not restrictive of the claimed subject matter.

### BRIEF DESCRIPTION OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principles of the concepts described herein. Like reference numerals may designate corresponding parts throughout the different views.

FIG. 1 is a flowchart of an example method for producing a structure including

a device, in accordance with some embodiments.

FIG. 2A is an atomic force micrograph of an example release liner carrier, in accordance with some embodiments.

FIG. 2B is an atomic force micrograph of an example release liner carrier with a resin film releasable substrate coated on a surface of the release liner carrier, in accordance with some embodiments.

FIG. 3 is a flowchart of an example method for producing a releasable substrate having a characteristic, in accordance with some embodiments.

FIG. 4 is a graph of light transmittance characteristics of an example releasable substrate formed on a release liner carrier with different concentrations of a UV-absorbing die, in accordance with some embodiments.

FIG. 5 illustrates an example system for carrying out methods disclosed herein, in accordance with some embodiments.

FIG. 6 illustrates an example method for using a finished electronic device on a transferable ultra-thin substrate, in accordance with some embodiments.

FIG. 7 illustrates another example system for carrying out methods disclosed herein, in accordance with some embodiments.

FIG. 8 provides examples of coater machines, printing machines, and laminator/delaminator machines, in accordance with some embodiments.

FIG. 9A is a top-down view of an example electronic device on an example transferable substrate, in accordance with some embodiments.

FIG. 9B is a photograph of an example device on an example transferable substrate, in accordance with some embodiments.

FIG. 9C is a cross-sectional side view of an example cell that may be part of a device on a transferable substrate, in accordance with some embodiments.

FIG. 9D is a cross-sectional side view of an example device on a transferable substrate, in accordance with some embodiments.

FIG. 9E is a diagram which illustrates an example process for making and using a device on a transferable substrate, in accordance with some embodiments.

FIG. 9F is a photograph of an example process and apparatus for using a device on a transferable substrate, in accordance with some embodiments.

FIG. 9G is a flowchart of an example method for producing a device on a transferable substrate, in accordance with some embodiments.

FIG. 9H is a diagram of an example system for making and using a device on a transferable substrate, in accordance with some embodiments.

FIG. 9I is an image which illustrates an example process for using a device on a transferable substrate, in accordance with some embodiments.

FIG. 9J is a graph and table illustrating example characteristics of a device on a transferable substrate, in accordance with some embodiments.

FIG. 10 is a cross-sectional side view of an example module of a device on a transferable substrate, in accordance with some embodiments.

FIG. 11A is an image of an example free-standing device on a transferable substrate, in accordance with some embodiments.

FIG. 11B is an image of an example device on a transferable substrate and laminated onto a composite fabric, in accordance with some embodiments.

FIG. 12 is a diagram of an example computing environment, in accordance with some embodiments.

FIG. 13 is a diagram of an example computer system, in accordance with some embodiments.

### DETAILED DESCRIPTION

Reference will now be made in detail to the embodiments of the disclosure, certain examples of which are illustrated in the accompanying drawings.

In the following description, numerous specific details are set forth regarding the concepts, systems, machines, methods, and devices of the disclosed subject matter, and the environment in which such systems, machines, methods, and devices operate, etc., to provide a thorough understanding of the disclosed subject matter. After reading the descriptions provided herein, it will be apparent to one skilled in the art, however, that the disclosed subject matter may be practiced without such specific details. It will also be apparent to one skilled in the art that certain features, which are well known in the art, are not described in detail to avoid unnecessary complication of the description of the concepts, systems, machines, methods, and devices described herein. In addition, it will be understood that the embodiments provided below are exemplary, and that it is contemplated that there are other systems, machines, methods, and devices that are within the scope of the concepts and subject matter disclosed herein.

Embodiments of the present disclosure relate to concepts and techniques for producing and using transferable ultra-thin substrates. These substrates may be, for example, less than 50 μm thick, though the disclosure is not so limited. More particularly, and without limitation, the present disclosure relates to concepts, systems and methods for producing transferable ultra-thin substrates in a manner that is efficient and scalable. The present disclosure further relates to concepts and structures that include devices on transferable ultra-thin substrates. The present disclosure further relates to use of structures that include the ultra-thin substrates and devices.

Also described is transfer lamination of releasable electronic devices onto permanent substrates. One example of a permanent substrate may be a fabric (e.g., any type of cloth or any other material). In some embodiments, the fabric may be a woven fabric or a non-woven fabric. In some embodiments, the fabric may be produced by weaving and/or knitting fibers. In some embodiments, the permanent substrate may be a ripstop type of fabric, such as a thermoplastic polyethylene (e.g., a high-modulus polyethylene). In some embodiments, the permanent substrate may be an ultra-high molecular weight polyethylene (UHMWPE), such as a composite fabric marketed by Aveint Corporation and provided under the name Dyneema®. In some embodiments, releasable electronic devices may be transferred to lightweight, high-strength composite substrates such as lightweight, high-strength composite fabrics (i.e., fabrics comprising two or more disparate materials) or other materials or substrates which otherwise would not lend themselves to direct integration into a manufacturing process for producing an electronic device. The ability to prepare and transfer such electronic devices onto permanent substrates enables use of electronic devices with a large number of different types of surfaces, including but not limited to fabrics. Such surfaces may be disposed on, around or about people. Thus, the concepts, systems, devices, and techniques described herein enable the realization of active, lightweight, flexible surfaces and the incorporation of such surfaces into a wide variety of systems.

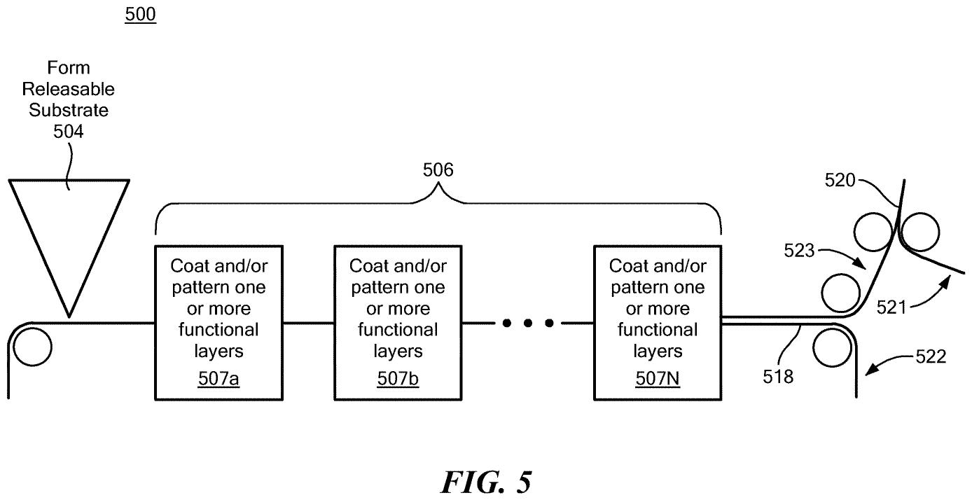

Thus, described herein are concepts, systems, machines, structures, devices, and techniques to prepare ultra-lightweight electronic devices via scalable manufacturing techniques (including but not limited to techniques discussed with reference to FIGS. 5, 7, FIGS. 8, and 9H). Also described is the integration of such devices (e.g., ultra-thin, ultra-lightweight photovoltaic (PV) devices) on other surfaces via transfer lamination. With the concepts, systems, machines, structures, devices, and techniques described herein, printed electronic devices on durable ultra-thin substrates may be disposed or otherwise integrated or added to other systems, circuits and/or devices.

The ability to manufacture electronic devices, such as PV devices, at all scales, ranging from several microns to many square meters in area, enables the concepts and technology described herein to find a place in a broad range of applications which may not be served in other ways. Printed electronic devices are appropriate for use (and in some cases may be ideal for use) in emerging applications such as wearables, internet-of-thing (IOT) devices, and on-skin/in-tissue diagnostic tools.

Scalable manufacturing of ultra-thin devices via the concepts and techniques described herein enable devices to carry out tasks, such as producing power or providing for wireless communication, while maintaining a small footprint. Coupling these benefits with the ability to process these devices on ultra-thin substrates (e.g., microns in thickness) allows ultra-thin electronic devices to enable a paradigm in which any surface of choice can be electrified with the use of an additive electronic device (e.g., much like a sticker) without noticeable addition in weight or topography. In particular, adding electronic functionality without much weight increase is critical in certain applications such as electric cars, unmanned aerial vehicles (drones), and on-skin electronics, where excess weight may overshadow the benefits of additional electronic capability, and serves as the primary obstacle to the integration of already-available silicon device alternatives.

More generally, it should be appreciated that the concepts, systems, structures, devices, and techniques described herein are not limited to any particular type of electronic device. Rather, the concepts, systems, structures, devices, and techniques described herein may be used in conjunction with any type of electronic and/or optoelectronic device. Thus, once a releasable substrate is created, any device including but not limited to PV, display (e.g., organic light-emitting diode (OLED)), sensor, radio frequency (RF) identification (ID) tag, antenna, or other computing architecture (e.g., flexible computer chips) may be disposed on or otherwise formed or coupled to the releasable substrate.

In one aspect, described is a technique for manufacturing a releasable device from a flexible carrier. Such a technique allows for a manufacturable process, because the flexible carrier is amenable for large-scale continuous manufacturing (e.g., roll-to-roll processing), as opposed to fabricating a device on a solid substrate (e.g., glass or silicon which require batch processing). It should be appreciated that the release of the device and releasable substrate from the release liner carrier does not necessarily need to occur before applying (e.g., adhering) the device to a permanent substrate. The release may occur before, simultaneously, or after applying the device to the permanent substrate.

Ultra-thin semiconductor devices (e.g., ultra-thin PV devices) can be prepared on premade substrates such as plastic films and metal foils, or on in-situ formed substrates such as chemical vapor deposited parylene or solution-processed polyimide. Owing to their extremely thin form and mechanical fragility, these devices are prepared on carrier substrates and may be delaminated upon completion of the device fabrication process. The presence of surface defects and thickness variation on premade ultra-thin substrates, along with challenges associated with handling such ultra-thin substrates prior to lamination onto a carrier have led to in-situ deposited substrates being more commonly used.

With the use of an additional encapsulation layer on top of a completed device, the overall geometries work out such that the functional components of the device can be located in a neutral plane, thereby limiting the mechanical-stress-damage to the device when flexed. Furthermore, device lamination onto pre-stretched elastomers allows for the formation of buckling structures which then show exceptional resilience under mechanical flexing and compression tests. In addition to PVs, there have been reports of a wide array of electronic and optoelectronic devices prepared in a similar fashion.

Present systems and methods employ solution-coated polyimide followed by an imidization reaction at 270 °C for two hours in a Nitrogen (N₂) atmosphere. However, these techniques may not be easy to scale, because the releasable substrates may be made on a rigid, fragile, hard-to-scale carrier (e.g., glass). These techniques may also be problematic because solution-coated substrates may need to be heated at high temperatures (e.g., 270 °C) for extended periods in a nitrogen-ambient environment in order to form the substrate. Another disadvantage of these techniques is that polyimide is an expensive material to use.

Another approach is to utilize a hybrid (vacuum and wet) coating/printing process. Systems and methods for using such an approach are described in U.S. Patent Application Publication No. 2023/0104867 (U.S. application Ser. No. 17/938,180), the disclosure of which is incorporated by reference herein in its entirety. This approach may utilize parylene (e.g., Parylene-C) as a releasable substrate. However, the deposition of parylene is performed with a vacuum process using chemical vapor deposition (CVD). This process may be slow and non-scalable. For example, the parylene deposition process may take several hours, owing to heating and cooling of a furnace system used in the process. Parylene deposition also requires high temperatures. As a result, a scalable roll-to-roll process of manufacturing ultra-thin electronic devices may not be possible if a vacuum, CVD process is required as part of the process. Utilizing a vacuum CVD process to deposit parylene has not yet been demonstrated in a scalable roll-to-roll production process.

Embodiments of the present disclosure encompass systems, methods, and devices that can address the problems associated with conventional techniques for producing ultra-thin transferable substrates. More particularly, and without limitation, the present disclosure relates to systems and methods for producing transferable ultra-thin substrates in a manner that is fast and scalable. Embodiments of the present disclosure may replace the vacuum CVD deposition process of parylene with solution-based processing, resulting in a faster and more scalable process for creating a releasable substrate. Example systems and methods disclosed herein may receive a release liner carrier, form a releasable substrate on the release liner carrier, and coat, print, and/or pattern one or more functional layers on top of the releasable substrate. For example, a release liner carrier may be received by a manufacturing system. The system may apply a solution to the release liner carrier to thereby create a releasable substrate. For example, the solution may include a soluble polymer resin (e.g., polyester) formulation, which when dried leaves a releasable substrate formed of the resin. The system may then apply one or more functional layers of coating, printing, and/or patterning to create a device on the releasable substrate. The one or more functional layers may be formed using solution-based processes, such as by coating, printing, and/or patterning the additional layers. As a result, a releasable substrate and device may be formed using only solution-based processes, resulting in a manufacturing process that is faster and more scalable, and more useful for production on a roll-to-roll manufacturing line.

In some embodiments, the device may be an electronic device, such as PV device. In some embodiments, the releasable substrate and device may be produced on a roll-to-roll manufacturing system. In other embodiments portions of the releasable substrate and/or device may be produced on different systems. In some embodiments, the manufacturing system may modify the solution for forming the releasable substrate to generate desired characteristics of the releasable substrate (e.g., ultraviolet (UV) light filtering characteristics). In some embodiments, the releasable substrate may be attached to the device but removable from the release liner carrier, such that a user can remove (e.g., peel) the release liner carrier from the releasable substrate and apply the releasable substrate and electronic device to an additional substrate (e.g., like a sticker). In some embodiments, after the release liner carrier has been removed from the releasable substrate, the release liner carrier may be reused for forming another device.

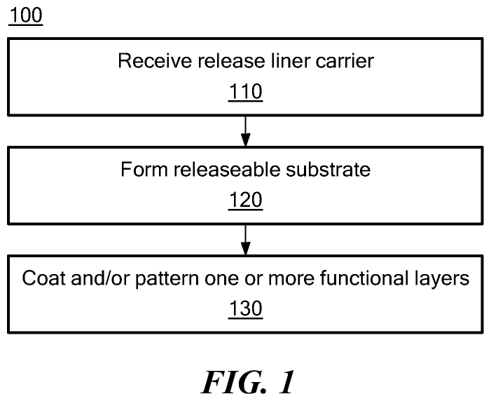

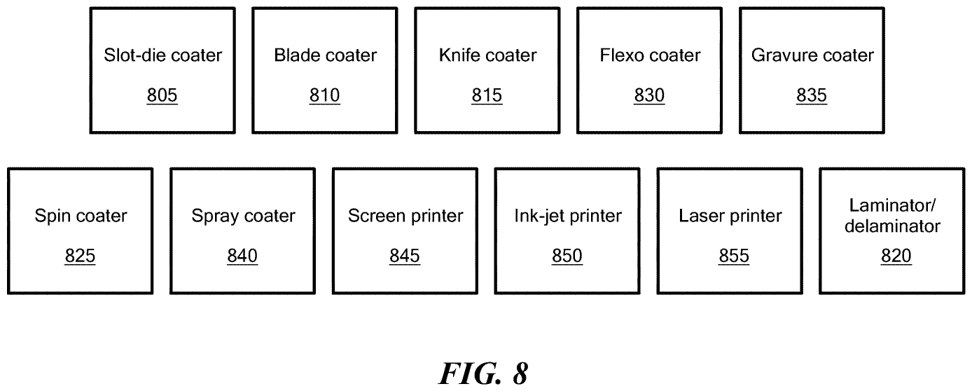

FIG. 1 illustrates an example method 100, consistent with embodiments of the present disclosure. Example method 100 may be implemented by one or more machines (see, e.g., FIG. 8) in one or more manufacturing systems (see, e.g., FIGS. 5, 7, 9H). In some embodiments, method 100 may be performed on a single roll-to-roll manufacturing system. In other embodiments, some or all of method 100 may be performed by one manufacturing system, while one or more additional portions of method 100 may be performed by another manufacturing system.

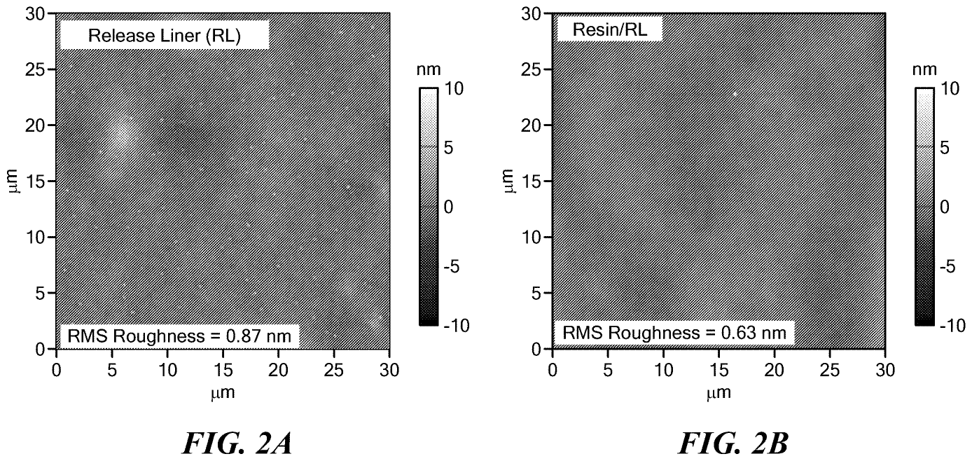

In 110, a release liner carrier (see, e.g., FIGS. 2A, 2B, 5, 7, 9C-9E, 9G, 9H, 10) may be received. For example, the release carrier liner may be received by a system (see, e.g., FIGS. 5, 7, 9H) including one or more machines (see, e.g., FIG. 8) for producing devices on ultra-thin transferable substrates. The release liner carrier may be made of a flexible material. The release liner carrier may be constructed of one or more materials selected based on characteristics such as chemical compatibility with resins dissolved in organic solvents, compatibility with scalable manufacturing processes (e.g., roll-to-roll compatible), surface energy, composite strength, flexibility, temperature stability, gauge variation, cost, transparency, adhesion, releasability, uniformity, appearance, and/or smoothness. In some embodiments, the release liner carrier may include a polyethylene terephthalate (PET) (e.g., polyester). The release liner carrier may also include a coating that may act as a release agent for later removing (e.g., peeling) the release liner carrier from another substrate. In some embodiments, the coating may be a silicone coating. For example, silicone-coated PET substrates used as medical liners, such as Saint Gobain 8799B may be used. Alternatively, the release liner carrier may include a fluorinated or fluorosilicone material. In some embodiments, the release liner carrier received by the system may already include a coating (e.g., silicone coating). For example, release liner carriers of this sort may be sourced from companies such as Saint-Gobain or Mitsubishi Plastics. In other embodiments, a release liner carrier may be received by a system and the system may add the coating (e.g., silicone coating) to the release liner carrier. For example, the coating may be added by slot-die coating (see, e.g., slot-die coater 805 of FIG. 8), blade coating (see, e.g., blade coater 810 of FIG. 8), knife coating (see, e.g., knife coater 815 of FIG. 8), flexo coating (see, e.g., flexo coater 830 of FIG. 8), gravure coating (see, e.g., gravure coater 835 of FIG. 8), spin coating (see, e.g., spin coater 825 of FIG. 8), or spray coating (see, e.g., spray coater 840 of FIG. 8) the coating onto the release liner carrier.

The coating of the release liner carrier may be provided to facilitate clean delamination of the release liner carrier from a releasable substrate and device to be formed on the release liner carrier, as will be further discussed below. In some embodiments, the coating may be made of a material that is transparent, thermally stable, mechanically stable, and/or chemically resistant. The coating may have a thickness below 50 nm. In some embodiments, the thickness uniformity of the coating may permit clean delamination of the releasable substrate and the device formed on the releasable substrate from the release liner carrier. The thickness uniformity of the coating may also permit formation of one or more functional layers of the device on top of the releasable substrate. As used herein, the phrase “clean delamination” may refer to delamination that does not stress the device formed on the releasable substrate in such a way that the device is damaged. In other words, the phrase “clean delamination” may refer to any delamination in which the device and releasable substrate are separated from the release liner carrier without being damaged. The ability to safely remove the device from the release liner carrier may be important for using the device in many commercial and industrial applications.

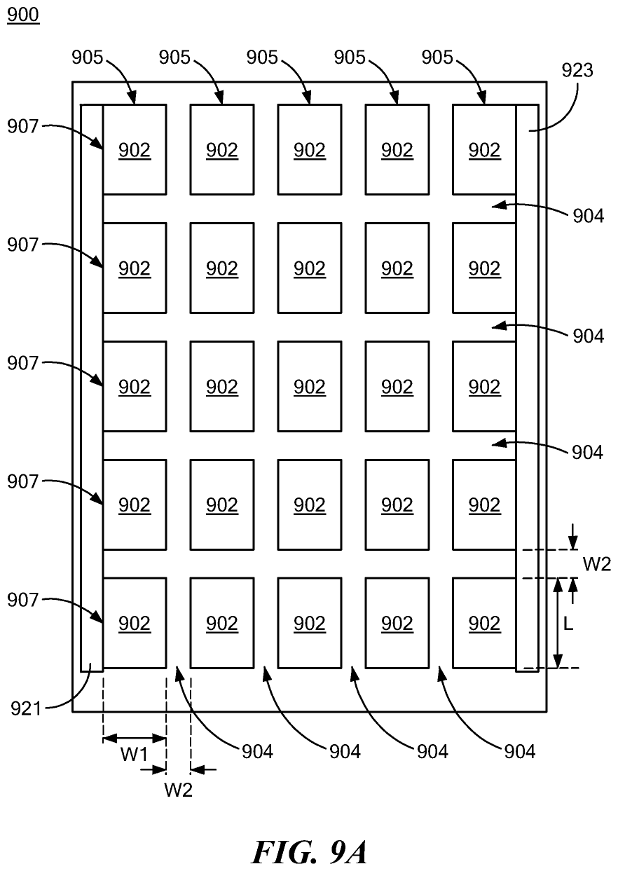

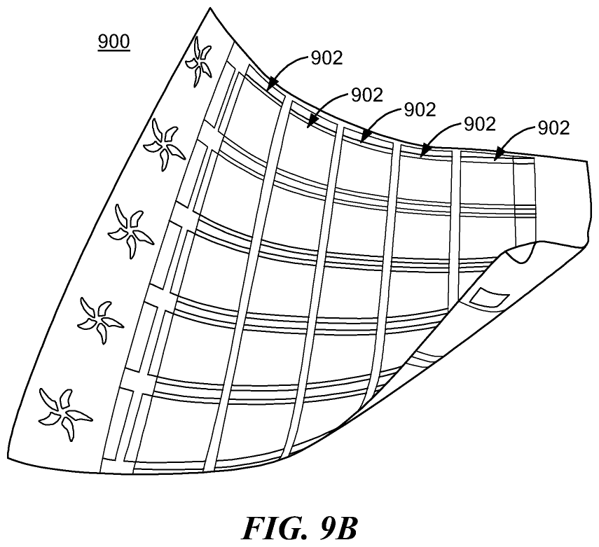

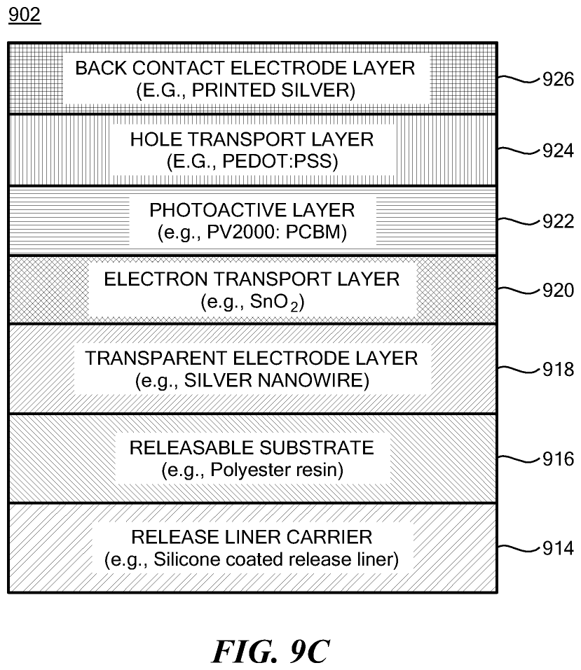

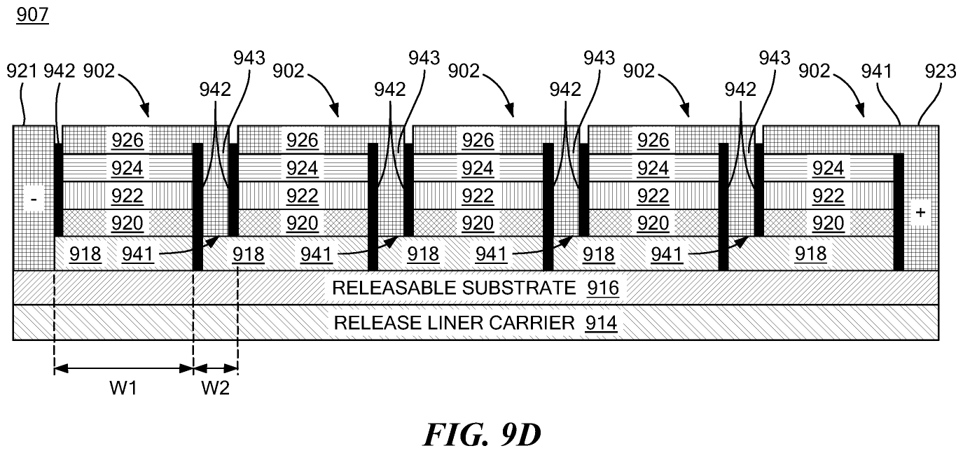

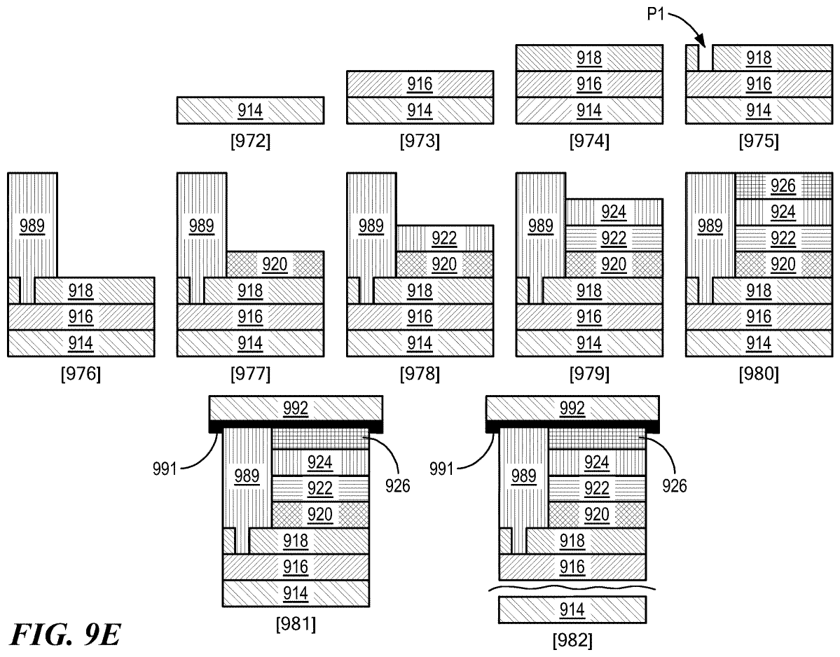

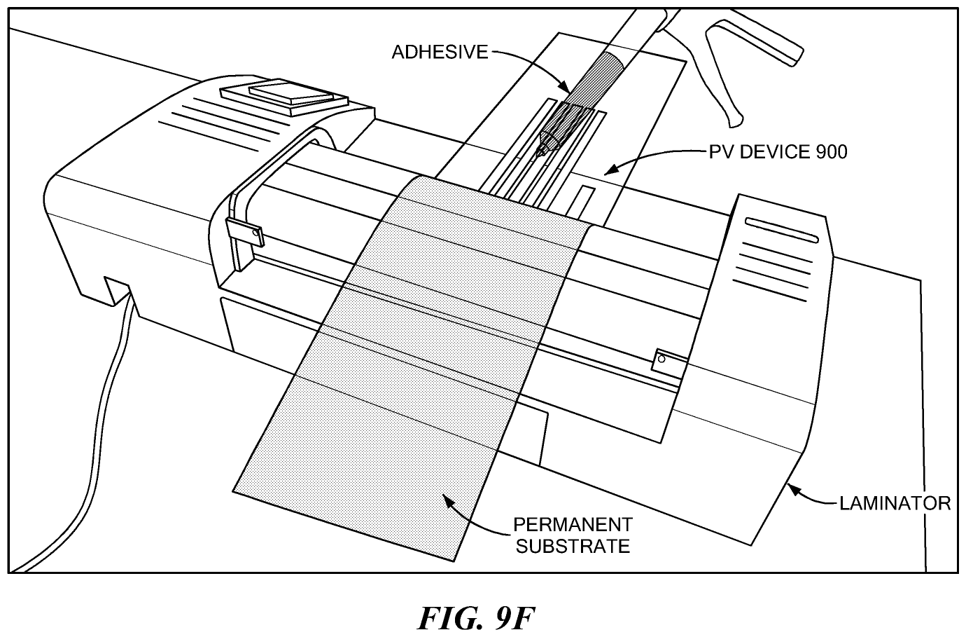

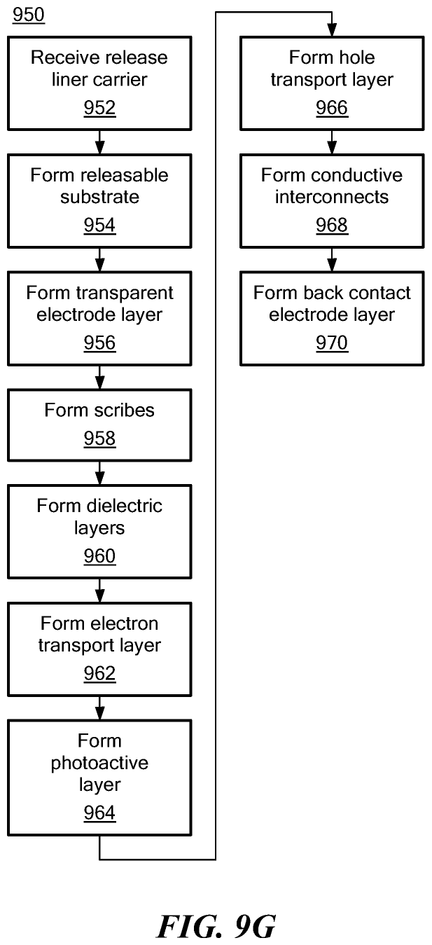

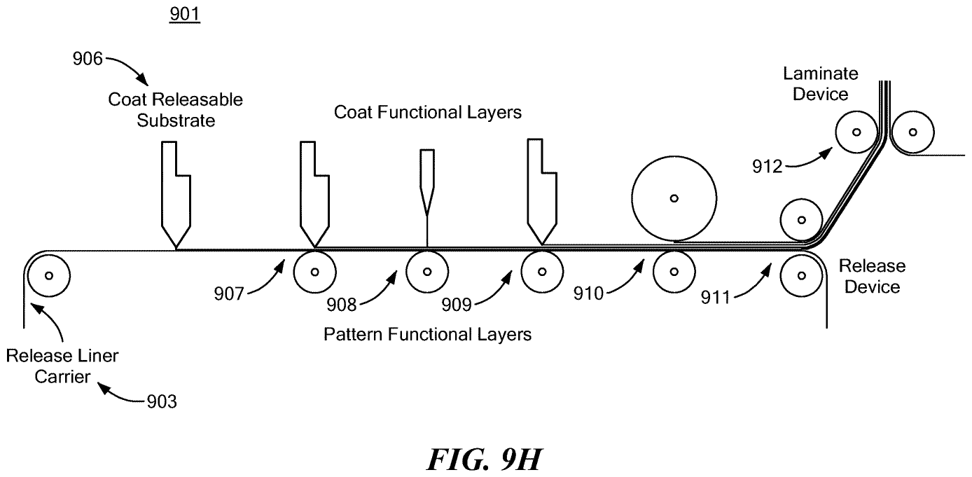

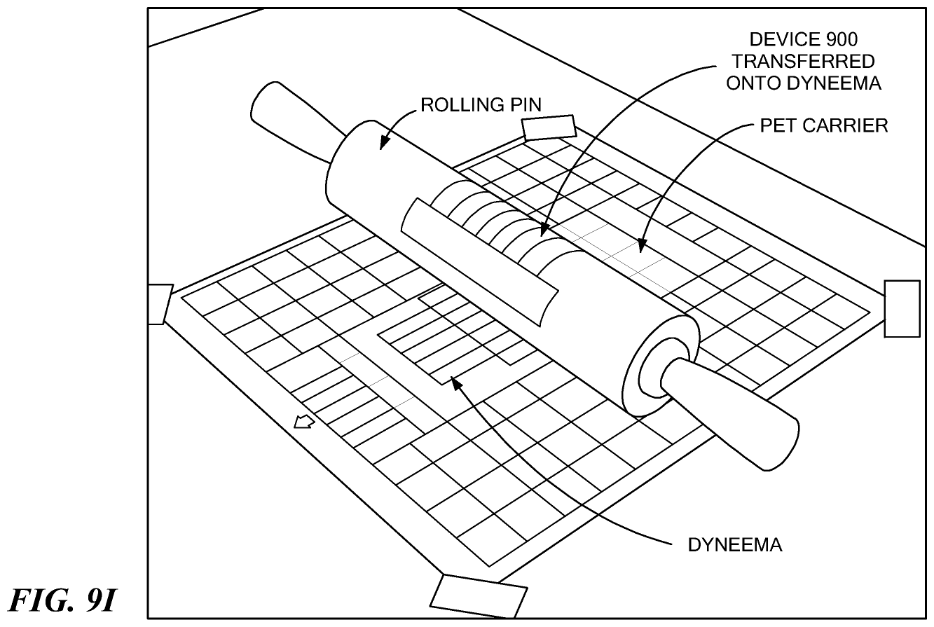

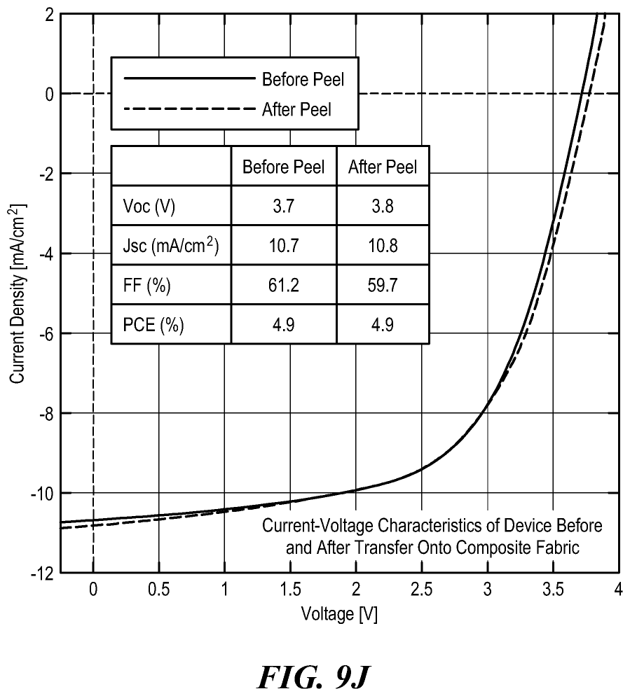

In some embodiments, the release liner carrier may be received by the system in an arrangement such that the release liner carrier will provide structural support to a device while the device is being manufactured by the system. In some embodiments, the device may be an electronic device. In some embodiments, the device is a PV electronic device (see, e.g., FIGS. 9A-9J, 10, 11A, 11B), though the disclosure is not so limited. Other example electronic devices that may be formed by the system include, for example, radio frequency (RF) circuits, integrated circuits, near field communication (NFC) or radio frequency identification (RFID) devices, antennas, transistors, sensors, or any other electronic device that can be printed on an ultra-thin substrate.

In 120, a releasable substrate may be formed on the release liner carrier. The releasable substrate may be formed of any material that has sufficient flexibility and strength to permit the releasable substrate and the device formed on the releasable substrate to be peeled (or otherwise delaminated) from the release linear carrier.

U.S. Patent Application Publication No. 2023/0104867 (U.S. application Ser. No. 17/938,180), the disclosure of which is incorporated by reference herein in its entirety, discusses approaches to forming a releasable substrate using parylene as a releasable substrate. However, the deposition of parylene is performed with a vacuum process using chemical vapor deposition (CVD), which may result in a process that is slow and non-scalable. For example, a vacuum, CVD process is a slow process that can take several hours. A vacuum, CVD process may also require high temperatures. Moreover, use of a vacuum, CVD process in forming ultra-thin transferable substrates may require moving production between different types of machines, such as between a machine capable of performing a vacuum, CVD process and other machines capable of solution-based (i.e., wet) coating/printing processes. As a result, a scalable roll-to-roll process for manufacturing ultra-thin electronic devices may not be possible if a vacuum, CVD process is required as part of the process. Utilizing a vacuum CVD process to deposit parylene has also not yet been demonstrated in a scalable roll-to-roll production process.

Embodiments of the present disclosure offer solutions to the problems associated with the processes described in U.S. Patent Application Publication No. 2023/0104867. For example, in 120, one or more machines (see, e.g., FIG. 8) in a manufacturing system (see, e.g., FIGS. 5, 7, 9H) may apply a solution to the release liner carrier to form a releasable substrate on the release liner carrier. The releasable substrate may be formed of any material that can be produced by applying a solution to the release liner carrier, and that has a sufficient flexibility and strength to permit the releasable substrate and the device formed on the releasable substrate to be peeled (or otherwise delaminated) from the release carrier liner. The solution may be a composition of one or more solutes in a solvent. For example, the solution may include a soluble resin, such as a polyester, in an organic solvent. Alternatively, the solution may be a solution that includes a resin such as polyvinylidene chloride (PVDC), polyvinylidene fluoride (PVDF) or an epoxy, and may be used to create a releasable substrate formed of PVDC, PVDF, or epoxy, respectively.

In some embodiments, the solution may be composed of a resin such as a solvent-based resin SKYBON ES-100 from SK Chemicals, SKYBON ES-120, or other resin solutions having substantially the same or similar characteristics, dissolved in an organic solvent. The organic solvent could be, for example, 2-pentanone, methyl ethyl ketone, methyl propyl ketone, or the like. The resin may be dissolved in the solvent in a range of about 10 to about 20% wt/wt radio (resin/solvent). The solution may be prepared at room temperature or up to about 60 °C to increase the rate of dissolution. Once formulated, the solution may have an extended shelf-life and may be able to be applied immediately or months later.

The solution may be applied using a large-area coating technique such as slot-die coating (see, e.g., slot-die coater 805 of FIG. 8), blade coating (see, e.g., blade coater 810 of FIG. 8), knife coating (see, e.g., knife coater 815 of FIG. 8), spin coating (see, e.g., spin coater 825 of FIG. 8), flexo coating (see, e.g., flexo coater 830 of FIG. 8), gravure coating (see, e.g., gravure coater 835 of FIG. 8), spray coating (see, e.g., spray coater 840 of FIG. 8), or may be printed using, for example screen printing (see, e.g., screen printer 845 of FIG. 8) or ink-jet printing (see, e.g., ink-jet printer 850 of FIG. 8). The solution may then be dried on the release liner carrier, such that the solvent dissolves, leaving a releasable substrate formed of the solutes (e.g., resin, such as polyester). In some embodiments, the releasable substrate may dry in an oven and be processed in ambient conditions. For example, the releasable substrate may dry in an oven in 2-5 minutes at 100 °C. In some embodiments, the thickness of the releasable substrate may be less than 1 micron. In some embodiments, characteristics of the releasable substrate, such as its thickness, may be varied by varying the concentration of the resin in the solution, the flow rate of the solution from the coating or printing machine, and/or the speed at which the release liner carrier moves through the manufacturing system (e.g., roll-to-roll manufacturing system).

The resulting releasable substrate may be smooth enough to fabricate devices (e.g., electronic devices) on. For example, FIG. 2A is an example atomic force micrograph of a release liner carrier, showing a root mean square roughness of 0.87 nm, and FIG. 2B is an atomic force micrograph of an example release liner carrier with a resin film releasable substrate coated on the surface of the release liner carrier, showing a root mean square roughness of 0.63 nm.

As will be further discussed herein, the remaining procedures for forming a device on the releasable substrate may similarly be performed with solution-based (i.e., wet) approaches. Thus, rather than forming a parylene releasable substrate using a vacuum, CVD process, and in place thereof forming a releasable substrate (e.g., resin, such as polyester) using a solution-based (i.e., wet) approach, a faster and more scalable process for manufacturing ultra-thin substrates can be provided.

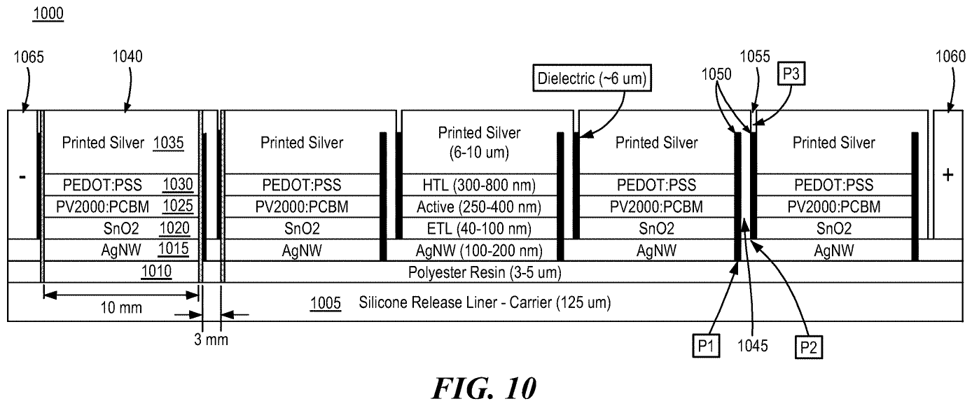

In 130, one or more functional layers of a device may be formed on the releasable substrate (see, e.g., FIGS. 9C-9E, 10). For example, one or more machines (see, e.g., FIG. 8) of a manufacturing system (see, e.g., FIGS. 5, 7, 9H) for producing a device (e.g., an electronic device) may form the one or more functional layers of the device. In some embodiments, a functional layer may be formed by applying a solution to the releasable substrate or to another functional layer that has already been formed. The functional layer may be formed of any material that can be produced by applying a solution to the releasable substrate or to another functional layer that has already been formed. The solution may be a composition of one or more solutes in a solvent. The solution may be sprayed or applied using a large-area coating technique such as slot-die coating (see, e.g., slot-die coater 805 of FIG. 8), blade coating (see, e.g., blade coater 810 of FIG. 8), knife coating (see, e.g., knife coater 815 of FIG. 8), spin coating (see, e.g., spin coater 825 of FIG. 8), flexo coating (see, e.g., flexo coater 830 of FIG. 8), gravure coating (see, e.g., gravure coater 835 of FIG. 8), or spray coating (see, e.g., spray coater 840 of FIG. 8). The solution may then be dried, such that the solvent dissolves, leaving a functional layer formed of the solutes.

In some embodiments, a functional layer may be formed by patterning a layer onto the releasable substrate or onto another functional layer that has already been formed. For example, a layer may be patterned by screen printing (see, e.g., screen printer 845 of FIG. 8), ink-jet printing (see, e.g., ink-jet printer 850 of FIG. 8), or laser printing (see, e.g., laser printer 855 of FIG. 8) a material onto the release substrate or onto another functional layer. In some embodiments, a laser printer (see, e.g., laser printer 855 of FIG. 8) may be used to form a functional layer by forming scribes in an already existing functional layer of the device.

130 may be repeated until a device has been formed. That is, 130 may be repeated such that multiple functional layers are formed in a stack structure until a device (e.g., an electronic device) has been formed on the releasable substrate. An example of forming one type of device, a PV device, will be further explained in detail with respect to FIGS. 9A-9J.

In some embodiments, a single machine (see, e.g., one of the machines provided in FIG. 8) of a manufacturing system (see, e.g., FIGS. 5, 7, 9H) may form multiple functional layers for a single electronic device, though the disclosure is not so limited. A single machine may also form only a single functional layer of an electronic device. Any number or combination of machines (see, e.g., example machines provided in FIG. 8), each being configured to coat/pattern some type and number of functional layers, may also be used in combination to form a device. For example, a roll-to-roll manufacturing system (see, e.g., FIGS. 5, 7, 9H) may be used, such that the release liner carrier is rolled, and as it is rolled, different machines form the releasable substrate and functional layers in a stack until finally the electronic device intended to be produced has been fully formed.

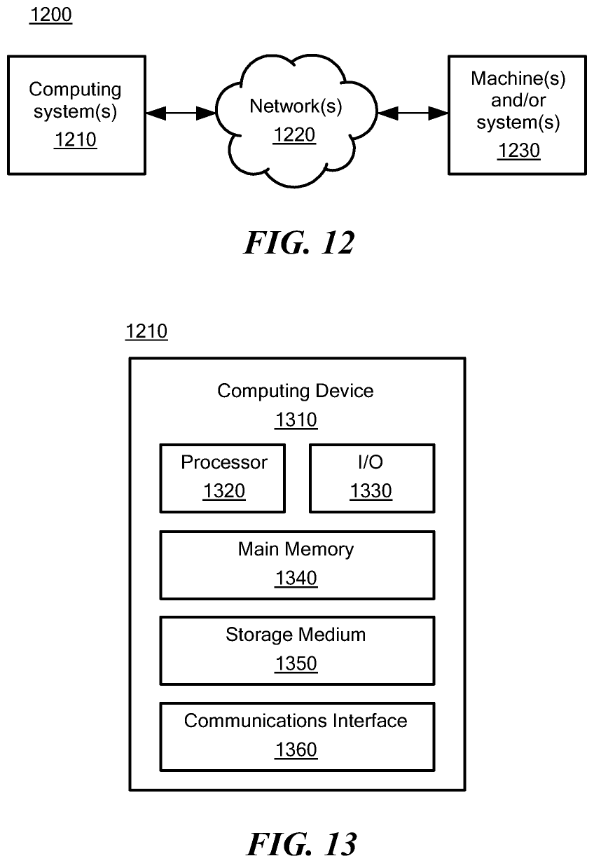

In some embodiments, method 100 may be implemented in a computing environment (see, e.g., computing environment 1200 of FIG. 12) using one or more computing systems (see, e.g., computing systems 1210 of FIGS. 12, 13). For example, one or computing systems 1210 (see, e.g., FIGS. 12, 13) may be connected with one or more machines (see, e.g., example machines of FIG. 8) and/or systems (see, e.g., example systems of FIG. 5, 7, 9H) 1230 over one or more networks 1220. Computing system(s) 1210 may be configured to control machine(s) and/or system(s) 1230 to implement one or more of 110, 120, and 130 of FIG. 1. For example, computing system(s) 1210 may control machine(s) and/or system(s) 1230 to receive a release liner carrier (110), such as by moving rollers of a manufacturing system. Computer(s) 1210 may control machine(s) 1230 to form a releasable substrate (120) by instructing machine(s) 1230 to apply a solution to the release liner carrier. Computing system(s) 1210 may control machine(s) 1230 to coat and/or pattern one or more functional layers (130) by instructing machine(s) 1230 to apply one or more solutions to the releasable substrate or to an already formed functional layer, or by instructing machine(s) 1230 to pattern an already formed functional layer using a laser, for example.

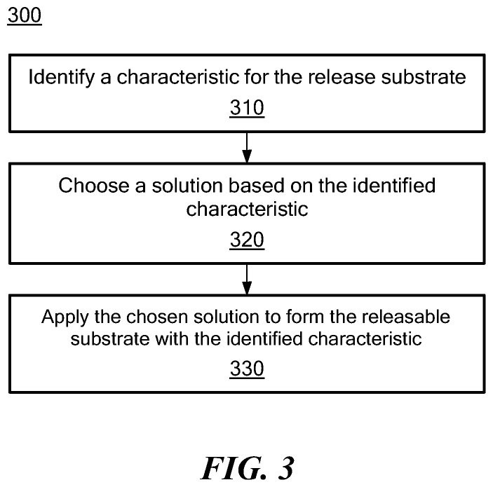

FIG. 3 illustrates an example method 300, consistent with embodiments of the present disclosure. Example method 300 may be implemented by one or more machines (e.g., FIG. 8) in a manufacturing system (see, e.g., FIGS. 5, 7, 9H). In some embodiments, method 300 may be performed by one or more machines in a roll-to-roll manufacturing system.

Method 300 may be performed as part of 120 of method 100 (see, e.g., FIG. 1). In some embodiments, method 300 may be performed as part of 120 to form a releasable substrate having certain desired characteristics. In 310, a desired characteristic for the releasable substrate is identified. The characteristic may be, for example, a thickness characteristic, an ultraviolet (UV) light filtering characteristic, a moisture barrier characteristic, an antireflective characteristic, a scratch resistance characteristic, or any other type of characteristic that can be added or modified by changing the composition of the solution to be applied to form the releasable substrate.

In 320, a solution may be chosen based on the identified characteristic. For example, a suitable solution may be chosen to form a releasable substrate having the identified characteristic. In some embodiments, the solution may be chosen by changing the composition of the solution to be applied. For example, the solution may be created having a certain concentration of one or more solutes in a solvent based on the identified characteristic. Alternatively, an existing solution may be modified to have a certain concentration of one or more solutes in a solvent based on the identified characteristic. In some embodiments, a variety of different solutions may have been premade to create releasable substrates of different characteristics, and 320 may involve selecting one of these solutions based on the identified characteristic.

In 330, the chosen solution may be applied to form the releasable substrate with the identified characteristic. For example, the chosen solution may be sprayed or applied using a large-area coating technique such as slot-die coating (see, e.g., slot-die coater 805 of FIG. 8), blade coating (see, e.g., blade coater 810 of FIG. 8), knife coating (see, e.g., knife coater 815 of FIG. 8), spin coating (see, e.g., spin coater 825 of FIG. 8), flexo coating (see, e.g., flexo coater 830 of FIG. 8), gravure coating (see, e.g., gravure coater 835 of FIG. 8), spray coating (see, e.g., spray coater 840 of FIG. 8), or the like. The solution may then be dried, such that the solvent dissolves, leaving a releasable substrate formed of the solutes and having the identified and desired characteristic.

As one example, UV light filtering capabilities of the releasable substrate may be tuned by varying the concentration of a UV-absorbing dye in the solution used for forming the release substrate. The UV-absorbing dye may be, for example, Uvinul® 3050, though the disclosure is not so limited.

In some embodiments, method 300 may be implemented in a computing environment (see, e.g., computing environment 1200 of FIG. 12) using one or more computing systems (see, computing systems 1210 of FIGS. 12, 13). For example, one or computing systems 1210 (see, e.g., FIGS. 12, 13) may be connected with one or more machines (see, e.g., example machines of FIG. 8) and/or systems (see, e.g., example systems of FIG. 5, 7, 9H) 1230 over one or more networks 1220. Computer(s) 1210 may be configured to control machine(s) and/or system(s) 1230 to implement one or more of 310, 320, and 330 of FIG. 3. For example, computing system(s) 1210 may control machine(s) and/or system(s) 1230 to identify a characteristic for the releasable substrate (310) (e.g., by receiving a user input or otherwise receiving an instruction regarding the characteristic). Computing system(s) 1210 may then choose a solution to apply based on the identified characteristic (320). For example, computing system(s) 1210 may store in memory a list of solutions that are available to be applied to generate substrates having certain characteristics, and may choose one of the solutions using, for example, a lookup table. Alternatively, computing system(s) 1210 may instruct machine(s) and/or systems 1230 to choose a solution based on the identified characteristic. Computing system(s) 1210 may then apply the chosen solution to form the releasable substrate with the identified characteristic (330). For example, computing system(s) 1210 may control machine(s) and/or system(s) 1230 to coat and/or pattern one or more functional layers by instructing machine(s) 1230 to apply one or more solutions to the releasable substrate or to an already formed functional layer, or by instructing machine(s) 1230 to pattern an already formed functional layer using a laser, for example.

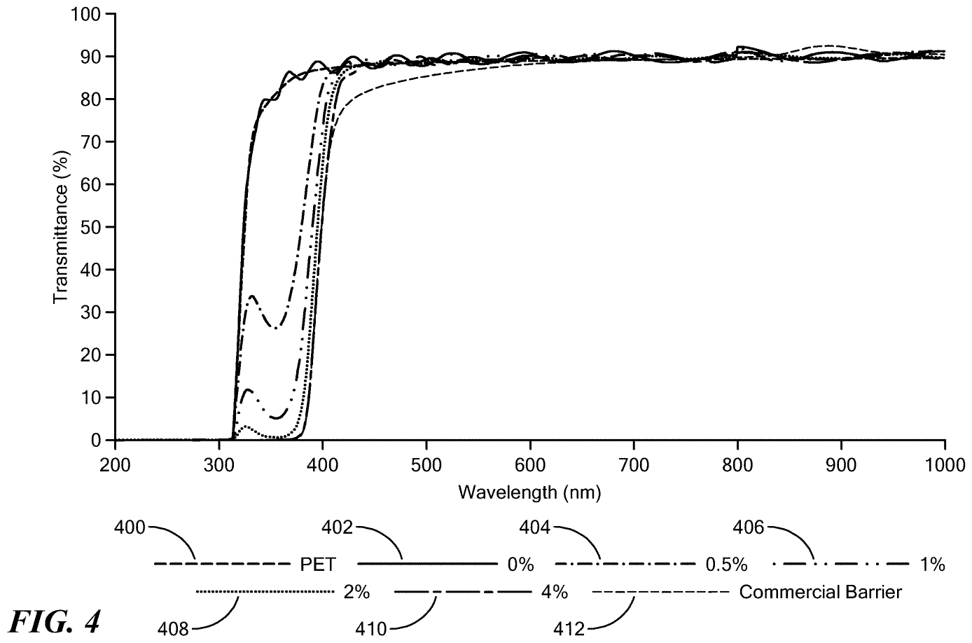

FIG. 4 is a graph illustrating light transmittance characteristics of an example releasable substrate formed on a PET (e.g., polyester) carrier with different concentrations of a UV-absorbing die. The y-axis of the graph represents a percent transmittance of light, and the x-axis of the graph represents different wavelengths of light. The 100-400 nm wavelengths of light are typically considered to be UV light. Curves 400-412 in the graph of FIG. 4 illustrate the percentage of light that may be transmitted through a releasable substrate at different wavelengths of light based on different concentrations of a UV-absorbing die added to the solution used to form the releasable substrate. For example, curve 404 illustrates transmittance percentages at different light wavelengths for a 0.5% concentration (by weight) of a UV-absorbing die, while curve 410 illustrates transmittance percentages at different light wavelengths for a 4% (by weight) concentration of a UV-absorbing die. Thus, as can be seen from FIG. 4, a greater concentration of the UV-absorbing die in the solution may result in a releasable substrate that filters a greater amount of UV light (i.e., there is a relationship between the percentage concentration of the UV-absorbing die in the solution and the amount of UV light which is absorbed).

As another example, a thickness of the releasable substrate may be tuned by varying a concentration of a solute in the solvent of the solution to be applied to form the releasable substrate. For example, a concentration of a resin (e.g., polyester) in an organic solvent may be increased if a greater thickness is desired, or may be decreased if a lesser thickness is desired.

As still another example, a water-vapor/oxygen barrier characteristic of a releasable substrate may be tuned by adding, for example, a layer of silicon nitride. Generally, the thicker the silicon nitride barrier, the greater the water-vapor/oxygen barrier capabilities of the releasable substrate, though forming a silicon nitride layer that is too thick may lead to cracking and reduce the water-vapor/oxygen barrier capabilities of the substrate.

In some embodiments, in 310 multiple characteristics may be identified and in 320 one or more solutions may be chosen based on the multiple characteristics. In 330, the chosen solution(s) may then be applied to form a releasable substrate having the multiple characteristics.

In some embodiments method 300 may be repeated to form a releasable substrate having multiple characteristics. For example, the process may be first performed to form a releasable substrate having UV filtering characteristics, and then another layer of the releasable substrate may be formed having moisture barrier characteristics.

FIG. 5 illustrates an example system 500 for carrying out method 100, method 300, method 600, and/or method 950. System 500 is an example roll-to-roll manufacturing system. A release liner carrier 522 may be received by the system (e.g., corresponding to 110 of method 100 and/or 952 of method 950). At 504, one or more machines (see, e.g., example machines of FIG. 8) may form a releasable substrate on the release liner carrier 522 (e.g., corresponding to 120 of method 100 and/or 954 of method 950). As discussed previously, the one or more machines may also perform method 300 to form the releasable substrate with certain characteristics. At 507a, one or more functional layers may be coated and/or patterned onto the releasable substrate (e.g., corresponding to 130 of method 100 and/or 956 of method 950). This may be repeated any number of times required to form all the functional layers of the device (see, e.g., example 507b . . . 507n, collectively 506, and/or 956-970 of method 950). At 518, the release liner carrier 522 may be removed from the releasable substrate and electronic device 523 (e.g., corresponding to 610 of method 600). The release liner carrier 522 may now be reused to form another electronic device (e.g., corresponding to 630 of method 600). At 520, the releasable substrate and electronic device 523 may be attached to a permanent substrate 521 (e.g., corresponding to 620 of method 600). The releasable substrate and electronic device 523 may be attached to the permanent substrate by laminating them to the permanent substrate, gluing them to the permanent substrate, or any other known technique for attaching two substrates. Lamination may include, for example, laminating through use of a UV curing adhesive (e.g., DELO LP655) using a pouch laminator. The permanent substrate may be any substrate capable of being attached to the releasable substrate and electronic device 523, and may include, for example, fabric, plastic, metal, wood, ceramics, glass, stone, or composite materials. In some embodiments, the permanent substrate may be a polymer fabric, such as a thermoplastic polyethylene (e.g., a high-modulus polyethylene) such as an ultra-high molecular weight polyethylene (UHMWPE) such as a composite fabric marketed by Aveint Corporation and provided under the name Dyneema®. Such a fabric may lend significant mechanical support to the electronic device and releasable substrate, without adding much weight to the overall system.

One of ordinary skill in the art would recognize that, although FIG. 5 illustrates a manufacturing process occurring on a single roll-to-roll manufacturing system, the disclosure is not so limited. Any portion of the manufacturing process may be performed by one or more machines (see, e.g., example machines of FIG. 8) on one system, and any number of one of more portions of the manufacturing process may be performed by one or more machines (see, e.g., example machines of FIG. 8) on another system. The disclosure is further not limited to roll-to-roll manufacturing systems. For example, a person of ordinary skill in the art would recognize that certain known batch-to-batch manufacturing systems could be used instead of a roll-to-roll manufacturing system. Moreover, certain portions of the manufacturing may be performed manually, while other portions may be performed by one or more machines (see, e.g., example machines of FIG. 8). For example, 518 and 520 of FIG. 5 may be performed manually. That is, once a finished electronic device has been formed on a releasable substrate and release liner carrier, at 518 a person may remove (e.g., peel) the release liner carrier 522 from the releasable substrate and electronic device 523, and then at 520 the person may attach the releasable substrate and electronic device 523 to a permanent substrate 521 (e.g., like a sticker).

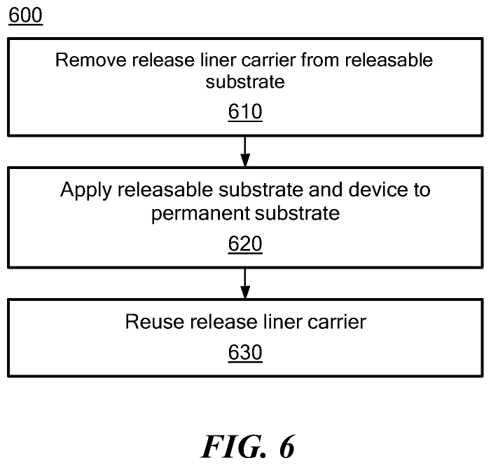

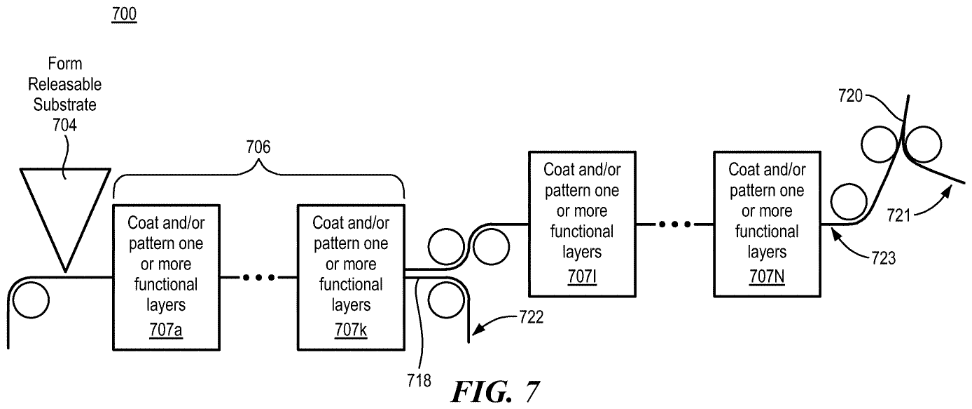

FIG. 6 illustrates an example method 600 for using a finished electronic device on a transferable ultra-thin substrate. Method 600 may be performed, for example, after a finished electronic device has been formed on a releasable substrate and release liner carrier (e.g., after method 100 is complete and/or after the processing in FIG. 5, FIG. 7, or FIG. 9H is complete). In 610, the release liner carrier may be removed from the releasable substrate. As discussed previously, an electronic device may have already been attached to the releasable substrate, so removing the release liner carrier from the releasable substrate may also remove the release liner carrier from the electronic device. Removing the release liner carrier from the releasable substrate may involve peeling the releasable substrate from the release liner carrier (e.g., like removing a sticker from its backing paper). The coating on the release liner carrier (e.g., silicone coating) may allow the releasable substrate and electronic device to be removed from the release liner carrier without putting too much stress or otherwise breaking the releasable substrate or electronic device.

In 620, the releasable substrate and device may be attached to a permanent substrate. As discussed previously, an electronic device may have already been formed on the releasable substrate, such that attaching the releasable substrate to the permanent substrate also causes the electronic device to be attached to the permanent substrate. As previously discussed, attachment to the permanent substrate may be performed through use of lamination, glue, or any other method of attaching two substrates. The permanent substrate may be any substrate capable of being attached to the releasable substrate and electronic device, and may include, for example, fabric, plastic, metal, wood, ceramics, glass, stone, or composite materials. In some embodiments, the permanent substrate may be an engineered polymer, such as a UHMWPE (e.g., composite fabric marketed as Dyneema® fabric). The electronic device may then be operated on the permanent substrate. For example, a PV device may be operated on the permanent substrate to generate electric power by using solar cells. This electric power may then be used to power equipment or to recharge batteries, for example.

In 630, the release liner carrier may be used again. That is, once the release liner carrier has been removed from the releasable substrate and electronic device, the release liner carrier can again be received by a manufacturing system for producing another electronic device. Reuse of the same release liner carrier may result in reduced production costs and/or be more sustainable (e.g., less harmful to the environment). In some embodiments, the same release liner carrier may be reused several times to produce several electronic devices.

Although FIG. 6 illustrates 610 occurring before 620, the disclosure is not so limited. In some embodiments, the releasable substrate and device may be applied to the permanent substrate (620) before the release liner carrier is removed from the releasable substate. For example, the top functional layer of the electronic device may be applied to the permanent substrate (e.g., adhered to the permanent substrate by lamination), and the release liner carrier then removed from the releasable substrate. In some embodiments, 610 and 620 may occur simultaneously. For example, the top functional layer of the electronic device may be applied to the permanent substrate (e.g., by lamination) at the same time the release liner carrier is removed from the releasable substrate.

In some embodiments, one or more portions of method 600 may be performed by one or more systems. For example, system 500 of FIG. 5 illustrates an example system that performs 610 (e.g., removing the release liner carrier 522 at 518) and 620 (e.g., applying the releasable substrate and electronic device 523 to a permanent substrate 521 at 520). In some embodiments, one or more portions of method 600 may be performed manually by one or more persons. For example, a person may remove (e.g., peel) the release liner carrier from the releasable substrate and electronic device and then apply the releasable substrate and electronic device to a permanent substrate of their choosing.

In some embodiments, method 600 may be implemented in a computing environment (see, e.g., computing environment 1200 of FIG. 12) using one or more computing systems (see, computing systems 1210 of FIGS. 12, 13). For example, one or computing systems 1210 (see, e.g., FIGS. 12, 13) may be connected with one or more machines (see, e.g., example machines of FIG. 8) and/or systems (see, e.g., example systems of FIG. 5, 7, 9H) 1230 over one or more networks 1220. Computing system(s) 1210 may be configured to control machine(s) and/or system(s) 1230 to implement one or more of 610, 620, and 630 of FIG. 6. For example, computing system(s) 1210 may control machine(s) and/or system(s) 1230 to remove a release liner carrier (610) from a releasable substrate, such as by instructing a delaminator (see, e.g., FIG. 8) to remove the release liner carrier from the releasable substrate. Computing system(s) 1210 may control machine(s) and/or system(s) 1230 to apply the releasable substrate and device to a permanent substrate (620), such as by instructing a laminator (see, e.g., FIG. 8) to adhere the releasable substrate and device to the permanent substrate. Computing system(s) 1210 may control machine(s) and/or system(s) 1230 to reuse the release liner carrier, such as by instructing system(s) 1230 to move rollers to receive the release liner carrier for reuse.

FIG. 7 illustrates an example system 700 for carrying out method 100, method 300, method 600, and/or method 950. System 700 is an example roll-to-roll manufacturing system. A release liner carrier 722 may be received by the system (e.g., corresponding to 110 of method 100 and/or 952 of method 950). At 704, one or more machines (see, e.g., example machines of FIG. 8) may form a releasable substrate on the release liner carrier 722 (e.g., corresponding to 120 of method 100 and/or 954 of method 950). As discussed previously, the one or more machines may also perform method 300 to form the releasable substrate with certain characteristics. At 707a, one or more functional layers may be coated and/or patterned onto the releasable substrate (e.g., corresponding to 130 of method 100 and/or 956 of method 950). This may be repeated any number of times required to form multiple layers of the device (see, e.g., example 707b . . . 707k, collectively 706, and/or 956-970 of method 950). At 718, the release liner carrier 722 may be removed from the releasable substrate and electronic device 723 (e.g., corresponding to 610 of method 600). The release liner carrier 722 may now be reused to form another electronic device (e.g., corresponding to 630 of method 600).

At 7071, one or more additional functional layers may be added. Note that, in contrast to system 500, here in system 700 the additional layer(s) added at 7071 may be added to a structure that already includes the releasable substrate and functional layers formed on the releasable substrate, but that no longer includes the release liner carrier. This may be repeated for any number of times required to form multiple layers of the device (see, e.g., example 7071 . . . 707k, and/or 956-970 of method 950). At 720, the releasable substrate and electronic device may be attached to a permanent substrate 721 (e.g., corresponding to 620 of method 600). The permanent substrate may be any substrate capable of being attached to the releasable substrate and electronic device 723, and may include, for example, fabric, plastic, metal, wood, ceramics, glass, stone, or composite materials. In some embodiments, the permanent substrate may be an engineered polymer such as UHMWPE (e.g., composite fabric marketed as Dyneema® fabric).

That is, in contrast to system 500 of FIG. 5, system 700 of FIG. 7 may form one or more functional layers on a releasable substrate while the releasable substrate is attached to a release liner carrier, and form additional functional layers on the already formed functional layers after the release liner carrier has been removed. Although FIG. 7 illustrates one system 700 for performing all portions of the manufacturing, the disclosure is not so limited. For example, 704-707k may be performed by one system that includes one or more machines (see, e.g., example machines of FIG. 8), while 707l-707n may be performed by another system that includes one or more machines (see, e.g., example machines of FIG. 8). The disclosure is further not limited to roll-to-roll manufacturing systems. For example, a person of ordinary skill in the art would recognize that certain known batch-to-batch manufacturing systems could be used instead of a roll-to-roll manufacturing system. Moreover, certain portions of the manufacturing may be performed manually, while other portions may be performed by one or more machines. For example, 718 and 720 of FIG. 7 may be performed manually. That is, once one or more functional layers have been formed on a releasable substrate and release liner carrier, at 718 a person may remove (e.g., peel) the release liner carrier 722 from the releasable substrate and electronic device 723. Later, at 720, when the entire electronic device has been formed, a person may attach the releasable substrate and electronic device 723 to a permanent substrate 721 (e.g., like a sticker).

One may recognize that there may be advantages to forming additional functional layers on the already formed functional layers and releasable substrate after the release liner carrier has been removed. For example, where multiple systems and/or manufacturers are involved, the first system/manufacturer may reuse the release liner carrier while the additional system/manufacturers add more functional layers. In doing so, the additional system/manufacturers would not need to transport the release liner carrier back to the first system/manufacturer for reuse. One may also recognize that there may be disadvantages with this approach compared to the approach of system 500 of FIG. 5. For example, the release liner carrier may provide important structural support in forming the functional layers of the electronic device, and without that support, the releasable substrate and/or functional layers of the stack may be more prone to breaking during manufacture. Additionally, a finished electronic device and releasable substrate without its release liner carrier may be fragile, making it challenging to transport for applying to a permanent substrate. For example, the release liner carrier may provide important structural support in transporting the electronic device and releasable substrate, in addition to providing important structural support in manufacturing the electronic device.

FIG. 8 provides example types of machines that may be used by systems (see, e.g., FIGS. 5, 7, 9H) in producing an electronic device. For example, FIG. 8 provides examples of machines that include a slot-die coater 805, a blade coater 810, a knife coater 815, a spin coater 825, a flexo coater 830, a gravure coater 835, and a spray coater 840. These machines may be used to apply a solution form a releasable substrate and/or one or more functional layers of an electronic device. FIG. 8 further provides examples of machines that include a screen printer 845, ink-jet printer 850, and laser printer 855. These machines may be used to print a solution to form a releasable substrate and/or or more functional layers of an electronic device. A laser printer 855 may also be used to etch an existing functional layer of an electronic device, such as to form scribes in a functional layer. FIG. 8 further provides an example laminator/delaminator 820 that may be used for peeling or otherwise delaminating a release liner carrier from a releasable substrate, and for laminating a releasable substrate and electronic device onto a permanent substrate. Alternatively, separate delamination and lamination devices may be used. Though example coater, printing, and laminator/delaminator machines are illustrated in FIG. 8, the disclosure is not limited to these machines. Any type of solution-based coater and/or printing machine may be used, consistent with the embodiments presented herein. Likewise, any machine that may be used to scribe a functional layer may be used in place of a laser printer 855, and any machine capable of peeling and/or adhering a device to a permanent substrate may be used in place of laminator/delaminator 820.

Additional details will now be provided with respect to an example type of device, a PV device, that may be manufactured consistent with the embodiments presented herein.

FIG. 9A illustrates an example flexible PV device 900, according to aspects of the disclosure. As illustrated, the PV device 900 may include a plurality of cells 902 separated by interconnection regions 904. In addition, the PV device 900 may include terminals 921 and 923, which are configured to connect the PV device 900 to external circuitry. Each of the cells 902 may have a width W1 and a length L, and each of the interconnection regions 904 may have a width W2. In one example embodiment, W1=10 mm, L=15 mm, and W2=3 mm. However, the concepts and structures are not limited to any specific dimensions for the cells 902 or interconnection regions 904. Although in the present example the PV device 900 includes twenty-five (25) cells, it will be understood that the present disclosure is not limited to the PV device 900 including any particular number of cells. In some applications, PV device 900 may comprise more than 25 cells while in other applications PV device 900 may comprise less than 25 cells. After reading the disclosure provided herein, those of ordinary skill in the art will appreciate how to select the number of cells to include for any particular application.

In some respects, the PV device 900 may be divided into stripes 905 and modules 907. In the example of FIG. 9A, a stripe 905 includes a column of cells 902 and an interconnection region 904 that is directly adjacent to the column. Furthermore, in the example of FIG. 9A, a module 907 includes a row of cells 902. As noted above, each stripe 905 may be 10 mm wide, with 3 mm for serial interconnection. In the example of FIG. 9A, each of the modules 907 includes 5 serially connected cells, each of size 1.5 cm², resulting in 7.5 cm² of active area per module. A cross-sectional side view of a module 907 is provided in FIG. 9D, which shows the interconnectivity between individual cells 902.

In embodiments, the PV device 900 may be manufactured in relatively large sheets (e.g., sheets having a size in the range of about 100 to about 1,000 square meters such as 1×100 meters). After manufacture, such sheets may subsequently be rolled before they are shipped to a customer or put in storage. As is discussed further below, the PV device 900 may be formed on a flexible release liner carrier. After the PV device 900 is manufactured, the carrier may be peeled off (or otherwise delaminated from the PV device 900) and the PV device 900 may be laminated over a permanent substrate. The permanent substrate may be a sheet of flexible material, such as fabric, or alternatively, the permanent substrate may be a panel of rigid or semi-rigid material. For example, in some implementations, the PV device 900 may be laminated over the roof of a tent, and used to provide power to people inside the tent. In another example, the PV device 900 may be laminated over a plastic base and used to form a solar panel this way.

Moreover, the PV device 900 is suitable for use in manufacturing settings in which the PV device 900 is both printed and laminated in the same manufacturing line. This is made possible by the PV device 900 being flexible and fully capable of being rolled. An example of an integrated manufacturing line for the production and lamination of the PV device 900 is shown in FIG. 9H.

FIG. 9B is an image of an example PV device 900. FIG. 9B is provided to illustrate that the PV device 900 may be flexible and thin. These characteristics make the PV device 900 especially suitable for mounting on fabric in roll-to-roll processing (see, e.g., FIG. 9H). The suitability for roll-to-roll processing of the PV device 900 may make the PV device 900 less costly to manufacture and use at scale than PV devices having similar electrical characteristics but which are relatively rigid PV devices as compared to the PV devices described herein.

FIGS. 9C and 9D show cross-sectional views of an example PV device 900, according to aspects of the disclosure. Specifically, FIG. 9C is a cross-sectional side view of an example individual cell 902 of PV device 900. FIG. 9D is a cross-sectional side view of an example entire module 907 of the PV device 900. FIG. 9C shows in greater detail examples of individual material layers that may be stacked to form the PV device 900, whereas FIG. 9D illustrates in greater detail example insulating layers and printed conductive interconnects between different cells 902 of PV device 900.

As illustrated, the PV device 900 may include a release liner carrier 914, a releasable substrate 916, a transparent electrode layer 918, an electron transport layer 920, a photoactive layer 922, a hole transport layer 924, and a back contact electrode layer 926.

The release liner carrier 914 may be arranged to provide structural support to the PV device 900 while the PV device 900 is manufactured, and before the PV device 900 is laminated onto a permanent base. In some implementations, the release liner carrier 912 may be a coated release liner carrier 914, such as a silicone-coated release liner like those that may be sourced from companies such as Saint-Gobain or Mitsubishi Plastics. For example, the release liner carrier 914 may be a silicone-coated polyethylene terephthalate (PET) sheet. However, the present disclosure is not limited to using any specific material to implement the release liner carrier 914.

In some implementations, release liner carrier 914 may have a root mean square (RMS) roughness of <5 nm. However, the present disclosure is not limited to any specific RMS roughness of release liner carrier 914. In some implementations, release liner carrier 914 may have a thickness in the range of 500-700 gauge, however the present disclosure is not limited to any specific thickness of the release liner carrier 914. In the examples of FIGS. 9C and 9D, the release liner carrier 914 is made of a flexible material. Alternative implementations are possible in which the release liner carrier 914 is made of rigid material. The coating on the release liner carrier 914 may be provided to facilitate clean delamination of the release liner carrier 914 from the releasable substrate and rest of PV device 900. The coating may be transparent, thermally stable, mechanically stable, or chemically resistant. In some embodiments, the coating may have a thickness below 50 nm. The thickness uniformity of the coating should be sufficient to permit clean delamination of releasable substrate 916 (and subsequent layers) from release liner carrier 914, as well as the formation of subsequent layers over release liner carrier 914.

As used herein, the phrase “clean delamination” may refer to a delamination that does not stress PV device 900 to the point at which PV device 900 is damaged. In other words, the phrase “clean delamination” may refer to any delamination in which PV device 900 is separated from release liner carrier 914 without being damaged. The ability to safely remove PV device 900 from release liner carrier 914 may be important for using PV device 900 in many commercial and industrial applications. Depending on the context, the term “PV device 900”, as used throughout the disclosure, may refer to all layers in the stack structure shown in FIG. 9C or only layers 918-926 or layers (or only layers 916-926).

The releasable substrate 916 may be formed over the release liner carrier 914. Releasable substrate 916 may be formed of any material that has sufficient flexibility and strength to permit releasable substrate 916, and the layers 918-926, to be peeled (or otherwise delaminated) from release liner carrier 914. In some implementations, the releasable substrate 916 may be formed from a solution. For example, a solution of a resin, such as a solvent-based polyester resin SKYBON ES-100 from SK Chemicals or other solutions having substantially the same or similar characteristics, may be dissolved in an organic solvent (e.g., 2-pentanone solvent) in a range of about 10 to about 20% wt/wt ratio (resin/solvent). The solution may be prepared at room temperature or up to about 60 °C to increase the rate of dissolution. Once formulated, the solution may have extended shelf-life and may be used immediately or months later. The solution may then be applied through one of a variety of different coating or printing methods, such as slot-die coating (see, e.g., slot-die coater 805 of FIG. 8), blade coating (see, e.g., blade coater 810 of FIG. 8), knife coating (see, e.g., knife coater 815 of FIG. 8), spin coating (see, e.g., spin coater 825 of FIG. 8), flexo coating (see, e.g., flexo coater 830 of FIG. 8), gravure coating (see, e.g., gravure coater 835 of FIG. 8), or spray coating (see, e.g., spray coater 840 of FIG. 8). In some implementations, the releasable substrate 916 may be 1-5 microns thick.

The transparent electrode layer 918 may be formed over releasable substrate 916. In some implementations, transparent electrode layer 918 may be formed by using silver nanowire (AgNW) ink (e.g., Heraeus™, Clevios HY E) with a printer, such as a screen printer (see, e.g., screen printer 845 of FIG. 8), ink-jet printer (see, e.g., ink-jet printer 850 of FIG. 8), or laser printer (see, e.g., laser printer 855 of FIG. 8). Additionally or alternatively, in some implementations, transparent electrode layer 918 may be formed by coating with a coater (see, e.g., slot-die coater 805, blade coater 810, knife coater 815, spin coater 825, flexo coater 830, gravure coater 835 and/or spray coater 840, of FIG. 8), and drying the coated sheets in an oven at 125 °C, for 5 minutes. It will be understood that the present disclosure is not limited to any specific method for making the transparent electrode layer 918. Additionally or alternatively in some implementations, transparent electrode layer 918 may be formed of a combination of PEDOT:PSS and silver nanowire ink.

After transparent electrode layer 918 is dried, the resulting structure may be laser-patterned (e.g., using laser printer 855 of FIG. 8) using an infrared laser (e.g., Xiaming Laser Company™, XM-20D) to create scribes 941 (shown in FIG. 9D). Each of the scribes 941 may be covered with a coated insulator (e.g., Creative Materials™, 111-27) to form a pair of dielectric layers 942. The insulator may be coated using any one or more of slot-die coater 805, blade coater 810, knife coater 815, spin coater 825, flexo coater 830, gravure coater 835, or spray coater 840, of FIG. 8. Dielectric layers 942 may limit yield losses due to edge defects from laser scribing, and may also define lanes within which subsequent layers (e.g., layers 920-924) would be coated. A respective conductive interconnect 943 may be formed between the dielectric layers 942 in each of the pairs of dielectric layers 942. Conductive interconnects 943 may be formed of the same material as the back contact electrode layer 926. In some implementations, both back contact electrode layer 926 and conductive interconnects 943 may be formed by printing silver ink over the structure that results after the hole transport layer 924 is formed. The silver ink may be printed, for example, using one or more of screen printer 845, ink-jet printer 850, or laser printer 855, of FIG. 8. As illustrated in FIG. 9D, the conductive interconnects may be used to form a serial electrical connection between the cells 902 in the module 907.

The electron transport layer 920 may be formed over transparent electrode layer 918. In some implementations, electron transport layer 920 may be formed by using tin-oxide and/or any other suitable type of material. Additionally or alternatively, in some implementations, electron transport layer 920 may be formed by coating tin-oxide nanoparticles (e.g., Avantama, N-31) onto transparent electrode layer 918 and drying the resulting structure in an oven at 120 °C, for 3 minutes. It will be understood that the present disclosure is not limited to any specific method or material for forming electron transport layer 920. The tin-oxide and/or other suitable material may be coated and/or printed using one or more of slot-die coater 805, blade coater 810, knife coater 815, spin coater 825, flexo coater 830, gravure coater 835, spray coater 840, screen printer 845, ink-jet printer 850, or laser printer 855, of FIG. 8.

The photoactive layer 922 may be formed with a photoactive ink, such as a blend of organic semiconducting compounds. The blend of organic semiconducting compounds may include derivatives of poly(3-hexylthiophene) (e.g., Raynergy-Tek™, PV2000) and phenylbutyric acid methyl ester (PCBM). Specifically, a photoactive ink may be prepared by dissolving the blend PV2000:PCBM (14 mg/mL) in o-xylene, and stirring overnight at 85 °C. Afterwards, the photoactive ink may be applied onto the electron transport layer 920 and dried in an oven at 120 °C, for 3 minutes. However, it will be understood that the present disclosure is not limited to using any specific method or material to form the photoactive layer 922. The photoactive ink may be coated and/or printed using one or more of slot-die coater 805, blade coater 810, knife coater 815, spin coater 825, flexo coater 830, gravure coater 835, spray coater 840, screen printer 845, ink-jet printer 850, or laser printer 855, of FIG. 8.

The hole transport layer 924 may be formed over photoactive layer 922. Hole transport layer 924 may be formed by applying poly(3,4-ethylenedioxythiophene) polystyrene sulfonate (PEDOT:PSS) over photoactive layer 922 and curing the resulting structure in an oven at 120 °C, for 3 minutes. However, it will be understood that the present disclosure is not limited to using any specific method or material to form hole transport layer 924. As can be readily appreciated, the positions of the hole transport layer 924 and the electron transport layer 920 may be interchanged in the stack shown in FIG. 9C. The material used in forming the hole transport layer may be coated and/or printed using one or more of slot-die coater 805, blade coater 810, knife coater 815, spin coater 825, flexo coater 830, gravure coater 835, spray coater 840, screen printer 845, ink-jet printer 850, or laser printer 855, of FIG. 8.

The back contact electrode layer 926 may be formed by applying silver ink (Heraeus™, SOL530B) over hole transport layer 924 and curing the resulting structure in an oven at 120 °C, for 3 minutes. However, it will be understood that the present disclosure is not limited to using any specific method or material to form back contact electrode layer 926. The silver ink may be coated and/or printed using one or more of slot-die coater 805, blade coater 810, knife coater 815, spin coater 825, flexo coater 830, gravure coater 835, spray coater 840, screen printer 845, ink-jet printer 850, or laser printer 855, of FIG. 8.

FIGS. 9C and 9D are provided to illustrate an example of one possible semiconductor structure that can be formed over the stack including release liner carrier 914 and releasable substrate 916. In this regard, it will be understood that the present disclosure is not limited to any specific type of semiconductor structure being formed on the stack including release liner carrier 914 and releasable substrate 916. As noted above, forming any semiconductor structure on a stack including release liner carrier 914 and releasable substrate 916 permits the semiconductor structure to be later laminated on a flexible or rigid base.

FIG. 9E is a diagram of an example of a process for making and using PV device 900, according to aspects of the disclosure. Although FIG. 9E shows the evolution of an individual cell 902 of PV device 900 through different process stages, it will be understood that the process described with respect to FIG. 9E applies to the entire PV device 900.

At 972, release liner carrier 914 is provided. At 973, releasable substrate 916 is formed over release liner carrier 914. At 974, transparent electrode layer 918 is formed over releasable substrate 916. At 975, a scribe 941 (labeled as P1) is formed in electrode layer 918. At 976, a structure 989 is formed in scribe 941 and over electrode layer 918. As discussed above with respect to FIG. 9D, the structure 989 may include a pair of dielectric layers 942. At 977, electron transport layer 920 is formed over transparent electrode layer 918. At 978, photoactive layer 922 is formed over electron transport layer 920. At 979, hole transport layer 924 is formed over photoactive layer 922. At 980, back contact electrode layer 926 is formed over hole transport layer 924. At 981, PV device 900 is laminated onto a permanent substrate 992 by using a layer of glue 991. The layer of glue 991 may include pressure-activated glue, light-activated glue, heat-activated glue, and/or any other suitable type of glue. At 982, the release liner carrier 914 is peeled off (or otherwise delaminated) from PV device 900.

In some implementations, 981 and 982 may be performed as follows. Tin-coated copper bus bars (Adhesive Research, ARcare 90038) may be electrically coupled to the terminals 921 and 923 (shown in FIGS. 9A and 9D). The receiving substrate of interest, in the present example, an engineered polymer, such as an UHMWPE (e.g., composite fabric marketed as Dyneema® fabric), may be laminated onto PV device 900, with the use of a UV curable adhesive (DELO™, LP655) and a pouch laminator (Akiles, ProLam Ultra X6). The entire assembly may be exposed to UV radiation (Amergraph Corporation™, V28 VMS) for 2 minutes and then subsequently placed on a hotplate, set to 80 °C, for 2 hours. Once annealed, all four sides may be trimmed, thereby creating a break in removable substrate 916 which was attached to release liner carrier 914. Next, PV device 900 may be delaminated off release liner carrier 914 simply by lifting the edge and rolling it off with a cylindrical rolling pin.

FIG. 9F is an example photograph of a PV device 900 being laminated onto a permanent substrate. In embodiments, the permanent substrate may be an engineered polymer such as a UHMWPE (e.g., composite fabric marketed as Dyneema® fabric). The engineered polymer and the PV device 500 are passed through a laminator with sufficient UV-activated adhesive dispensed in between the two. FIG. 9F is provided to illustrate a non-limiting example of the application of the PV device 900 in a lab or small-scale setting.

FIG. 9G illustrates an example method 950 for forming an electronic device (e.g., a PV device 900) on a transferable ultra-thin substrate, consistent with embodiments of the present disclosure. In 952, a release liner carrier may be received. At 954, a releasable substrate may be formed over the release liner carrier. At 956, a transparent electrode layer may be formed over the releasable substrate. At 958, a scribe may be formed in the electrode layer. At 960, a structure may be formed in the scribe and over the electrode layer. As discussed above with respect to FIG. 9D, the structure 989 may include a pair of dielectric layers 942. At 962, an electron transport layer may be formed over the transparent electrode layer. At 964, a photoactive layer may be formed over the electron transport layer. At 966, a hole transport layer may be formed over the photoactive layer. At 968, a conductive interconnect may be formed between the pair of dielectric layers. At 970, a back contact electrode layer may be formed over the hole transport layer.

In some embodiments, method 950 may be implemented in a computing environment (see, e.g., computing environment 1200 of FIG. 12) using one or more computing systems (see, computing systems 1210 of FIGS. 12, 13). For example, one or computing systems 1210 (see, e.g., FIGS. 12, 13) may be connected with one or more machines (see, e.g., example machines of FIG. 8) and/or systems (see, e.g., example systems of FIG. 5, 7, 9H) 1230 over one or more networks 1220. Computing system(s) 1210 may be configured to control machine(s) and/or system(s) 1230 to implement one or more of 952, 954, 956, 958, 960, 962, 964, 966, 968, and 970 of FIG. 9G. For example, computing system(s) 1210 may control machine(s) and/or system(s) 1230 to receive a release liner carrier (952), form a releasable substrate (954), form a transparent electrode layer (956), form scribes (958), form dielectric layers (960), form an electron transport layer (962), form a photoactive layer (964), form a hole transport layer (966), form conductive interconnects (968), and/or form a back contact electrode layer 970).

FIG. 9H is an example system 901 for manufacturing and using the PV device 900 by using a roll-to-roll manufacturing line. For example, system 901 may be used to form a releasable substrate and electronic device using method 950 of FIG. 9G. At 903, a release liner carrier may be received and fed through the manufacturing line. As discussed above, the release liner carrier may be a coated release liner carrier, such as a silicone coated released liner carrier. The silicone coated release liner carrier may be commercially available. Alternatively, the release liner carrier may be formed by coating a material (e.g., silicone) onto a PET carrier. At 906, a releasable substrate may be formed on the release liner carrier using one or more machines (see, e.g., example machines of FIG. 8). As discussed above, the releasable substrate may be formed by applying a solution to the release liner carrier and allowing the solution to dry. In some embodiments, the releasable substrate is a resin (e.g., polyester) substrate that is formed by applying a solution of the resin in an organic solvent and allowing the solution to dry. At 907, a transparent electrode layer is formed on the releasable substrate. As noted above, the transparent electrode layer may be formed by coating or printing (e.g., using one or more example machines of FIG. 8) the releasable substrate with silver nanowire ink. At 908, the resulting structure may be laser-patterned (e.g., using laser printer 855 of FIG. 8) to form scribes (shown, e.g., in FIG. 9D). At 909, dielectric layers may be formed (e.g., using one or more example machines of FIG. 8), and the electron transport layer, photoactive layer, and hole transport layer may be formed (e.g., using one or more example machines of FIG. 8). At 910, the conductive interconnects may be formed (e.g., using one or more example machines of FIG. 8) and the back contact electrode layer may be formed (e.g., using one or more example machines of FIG. 8). At 911, the release liner carrier may be delaminated (e.g., using a delamination machine) from the PV device. At step 912, the PV device may be laminated (e.g., using a pouch laminator) onto a permanent substrate. According to the present disclosure, the permanent substrate may include an engineered polymer, such as a UHMWPE (e.g., composite fabric marketed as Dyneema® fabric). However, the present disclosure is not limited to any specific type of material being used as a permanent substrate for the device. In some implementations, the PV device may be printed in stripes by the manufacturing line.

The composite fabric marketed as Dyneema® fabric, made of ultra-high molecular weight polyethylene fibers sandwiched between sheets of mylar, may be one of the best materials commercially available for high-strength, low-weight applications. At 13 grams per square meter, and over 5 kN/m in tensile strength, the lightest offering of Dyneema® fabric may present itself as a highly suitable receiving substrate of the ultra-thin solar devices. It may lend significant mechanical support without adding much weight to the overall system. As noted above in the example of FIG. 5, the PV device 900 may be transfer-laminated with the use of a UV curing adhesive (DELO LP655). Employing a pouch laminator, the two films may be sandwiched with ample adhesive to ensure no dry spots and air bubbles are formed. Once UV cured, trimming the edges of the assembly may create a break between the releasable substrate 916 and the release liner carrier 914, and allow for swift delamination of the release liner carrier 914 from the assembly including the PV device 900 and the Dyneema® fabric.

Device testing before and after delamination shows comparable performance. For example, FIG. 9J illustrates characteristics of a test device before and after delamination. The plots in the graph illustrate current voltage characteristics of a test device before being peeled from the release liner carrier and after being peeled from the release liner carrier. As can be seen, the before peel and after peel devices show comparable current voltage performance. FIG. 9J, and Table 1 below, further illustrates properties of the test devices before and after peel, such as open circuit voltage (Voc) characteristics, short-circuit current density (Jsc) characteristics, fill factor (FF) characteristics, and power conversion efficiency (PCE) characteristics.

TABLE 1

| | Before | After |
|---|---|---|
| | Peel | Peel |
| Voc [V] | 3.7 | 3.8 |
| J_{SC} [mA/cm²] | 10.7 | 10.8 |
| FF [%] | 61.2 | 59.7 |
| PCE [%] | 4.9 | 4.9 |

In some instances, important to fully realize the potential of the techniques described with respect to FIGS. 9A-H may be the availability of equally ultra-lightweight encapsulation barriers that can protect the active layers of fabric-PVs from atmospheric exposure, which in turn can extend the operational lifetime of these devices, as needed for real-world applications. Currently available packaging films would significantly increase the weight of these structures and limit the value of developing these ultra-lightweight device form factors. Likewise, translation of higher efficiency active material sets such as thin-films of perovskites or of recently reported non-fullerene-based organic systems can further expand the domain of applications that can be addressed with this technology. Moreover, systems-level integration of devices (such as the PV device 900) with power-electronic circuits, and storage elements could be important for the technology to transition from lab-based demonstrations to consumer-ready technology.

FIG. 9I illustrates a delamination of a PV device 900 from a release liner carrier onto a Dyneema fabric after UV exposure. An adhesive mat may be used to stabilize the release liner carrier while the PV device 900 is delaminated with a rolling pin. FIG. 9I is provided to illustrate a non-limiting example of the application of a PV device 900 in a lab or small-scale setting.

FIG. 10 illustrates an example cross section of a module 1000 of a PV device 900, which may be the same PV device as PV device 900 described with respect to FIGS. 9A-9J. As shown in FIG. 10, PV device 900 may include a silicone coated release liner carrier 1005. Alternatively, the release liner carrier may include a fluorinated or fluorosilicone material. The release liner carrier 1005 may extend across all cells 1040 of PV device 900. In some embodiments, the release liner carrier 1005 may be approximately 125 μm in thickness, though the disclosure is not so limited. Depending upon the requirements of a particular application or a particular manufacturing process, the release liner carrier may have a thickness in the range of about 50 μm to about 150 μm, though the disclosure is not so limited. PV device 900 may also include a polyester resin releasable substrate 1010. The releasable substrate 1010 may also extend across all cells 1040 of PV device 900. In some embodiments, the releasable substrate 1010 may be approximately 3-5 μm in thickness, though the disclosure is not so limited.

In the example shown in FIG. 10, five cells 1040 are created for each module 1000 of PV device 900. In some embodiments, each cell 1040 may be approximately 10 mm in width, with interconnection areas between the cells having an approximate width of 3 mm. As shown in FIG. 10, each cell 1040 may include a transparent electrode layer 1015, an electron transport layer 1020, a photoactive layer 1025, a hole transport layer 1030, and a back contact electrode layer 1035, though the disclosure is not so limited.

In the example shown in FIG. 10, the transparent electrode layer 1015 of each of the five cells 1040 may be formed of an electrically conductive nanowire such as a silver nanowire. In some embodiments, the transparent electrode layer 1015 may be in the range of about 100 nm-to about 200 nm in thickness, though the disclosure is not so limited.

In the example shown in FIG. 10, the electron transport layer 1020 of each of the five cells 1040 may be formed of a tin-oxide (SnO₂). Additionally or alternatively, the electron transport layers 1020 may be formed by coating tin-oxide nanoparticles (e.g., Avantama, N-31) on to the transparent electrode layer 1015 and drying the resulting structure in an oven at 120 °C for 3 minutes. In some embodiments, the electron transport layer 1020 may be approximately 40-100 nm in thickness, though the disclosure is not so limited.

In the example shown in FIG. 10, the photoactive layer 1025 of each of the five cells 1040 may be formed of a blend of organic semiconducting compounds, such as derivatives of poly(3-hexylthiophene) (e.g., Raynergy-Tek™ PV2000) and phenylbutyric acid methyl ester (PCBM). More specifically, a photoactive ink may be prepared by dissolving a blend PV2000:PCBM (14 mg/mL) in o-xylene, and stirring overnight at 85 °C. Afterwards, the photoactive ink may be coated onto the electron transport layer 1020 and dried in an oven at 120 °C, for 3 minutes. In some embodiments, the photoactive layer may have a thickness of approximately 250-400 nm, though the disclosure is not so limited.

In the example shown in FIG. 10, the hole transport layer 1030 of each of the five cells 1040 may be formed by coating poly (3,4-etyhlenedioxythiophene) polystyrene sulfonate (PEDOT:PSS) over the photoactive layer 1025 and curing the resulting structure in an oven at 120 °C, for 3 minutes. In some embodiments, the hole transport layer 1030 is approximately 300-800 nm in thickness, though the disclosure is not so limited.

In the example shown in FIG. 10, the back contact layer 1035 of each of the five cells 1040 may be formed by screen printing silver ink (Heraeus™, SOL530B) over the hole transport layer 1030 and curing the resulting structure in an oven at 120 °C, for 3 minutes. In some embodiments, the back contact electrode layer 1035 is approximately 6-10 μm in thickness, though the disclosure is not so limited.

In the example shown in FIG. 10, scribes 1055 (also labeled as P3) may be formed between each of the five cells of the module. Within the scribes 1055, a pair of dielectric layers 1050 (also labeled as P1) may be formed between each set of cells 1040. In some embodiments, each dielectric layer 1050 may be approximately 6 μm in width, though the disclosure is not so limited.

In the example shown in FIG. 10, a conductive interconnect 1045 (also labeled as P2) may be formed to pass between the printed silver coating of the back contact electrode layer 1035 and the silver transparent electrode layer 1015. A positive terminal 1060 and negative terminal 1065 may be provided at either end of the module 1000 to receive electrical power generated by the cells 1040 of the module 1000.

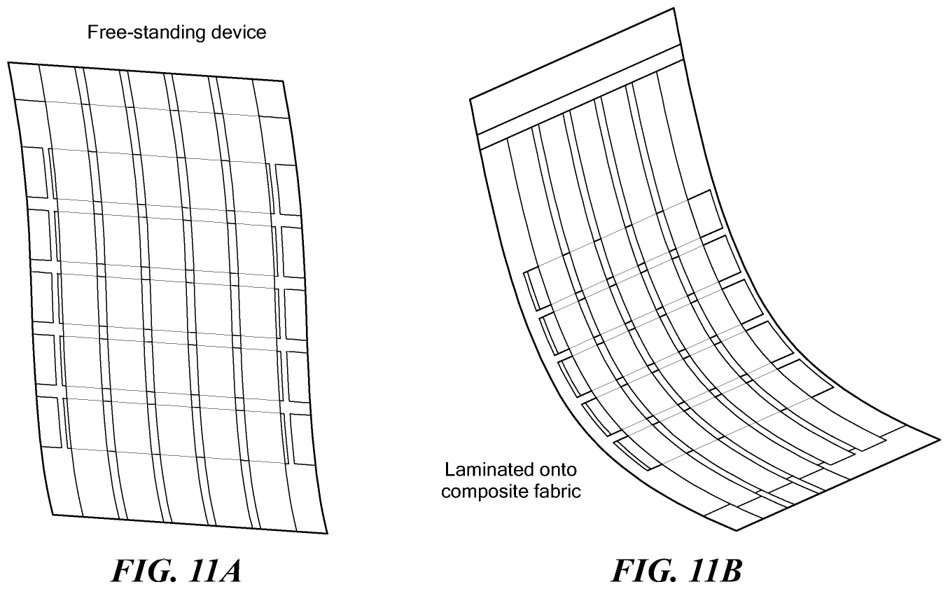

FIG. 11A is an example picture of a free-standing test PV device. That is, the PV device illustrated in FIG. 11A has been removed (e.g., peeled) from its release liner carrier. FIG. 11B is an example picture of a test PV device that has been applied to a permanent substrate. In this case, the test PV device was laminated onto a composite fabric.

The discussion that follows presents further aspects of PV devices, such as PV device 900, as well as further aspects of processes for making and using the PV devices.

### A. Process for Preparing the Release Liner Carrier, Releasable Substrate, and Transparent Electrode Layer of a PV Device

This section describes example aspects of the preparation of the release liner carrier, the releasable substrate, and the transparent electrode layer of a PV device, such as PV device 900. Though glass has been the carrier material of choice in literature for preparing such ultra-thin devices, it does not readily lend itself to integration into large-area coating techniques such as slot-die coating and screen printing. Owing to the brittle nature of glass and its inability to be slit and trimmed with ease, the present disclosure instead discusses flexible release liner carriers. For example, polyethylene terephthalate (PET) sheets may be used. These PET sheets may be coated to allow for delamination of the release substrate and electronic device. For example, the PET sheets may be coated with silicone.

Coatable materials for a transparent electrode may include highly conducting poly (3,4-ethylenedioxythiophene) polystyrene sulfonate (PEDOT:PSS), silver nanowires (AgNW), and screen-printed silver meshes. As discussed above, the example of FIGS. 9A-9E describes use of silver nanowire ink. However, alternative implementations are possible in which the transparent electrode layer is formed of PEDOT:PSS or a combination of PEDOT:PSS and silver nanowire ink. The ink may be coated onto the substrate with the use of a slot-die sheet-to-sheet coater. In one aspect, optimized coating conditions may lead to a transparent (~85% transmittance) and conductive (15-17 Ω/sq) layer. In another aspect, use of the PEDOT:PSS matrix may lead to (1) reduced surface roughness, as compared to films of nanowires coated without any filler; and (2) isotropic sheet resistance which may otherwise be affected by selective orientation of nanowires during the coating process. According to the present disclosure, several points on multiple coated test sheets were measured, both in the coating and transverse directions, and the calculated average of sheet resistances in the respective directions were 16.4 Ω/sq and 17.4 Ω/sq demonstrating the conductance isotropy.

Once formed, the transparent electrode may be patterned with an infrared laser to create scribes, such as the 941 scribes which are discussed above with respect to FIG. 9D. As discussed above, in the example of FIGS. 9A-9E, scribes may be spaced 13 mm apart with the intention of creating modules with 10 mm wide cells and 3 mm wide interconnects. An example schematic of the module geometry is discussed above with respect to FIG. 9D. Laser ablation of the silver nanowire films may result in edge defects, which may pose a risk to electrical shorts in the device and may limit overall yields in a scaled manufacturing process. To prevent such issues, the scribes may be encapsulated with a slot-die coated insulator, which also may define the lanes in which subsequent layers (e.g., conductive interconnect 943) are to be coated in.

### B. Process for Preparing the Electron Transport Layer, the Hole Transport Layer, the Active Layer, and the Top Electrode of a PV Device

This section describes example aspects of the preparation of the electron transport layer, the hole transport layer, the active layer, and the top electrode layer of a PV device, such as PV device 900. It will be recalled that in the example of FIGS. 9C-E, the transparent electrode layer of PV device 900 may be formed of silver nanowire, the electron transport layer 920 may be formed of tin-oxide, the photoactive layer 922 may be formed of PV200:PCBM, the hole transport layer 924 may be formed of PEDOT:PSS, and the back contact electrode layer 926 may be formed of screen-printed silver. The root-mean-square roughness of the coated nanowire films may be 11.8 nm over a 20 μm×20 μm scan range and may be further reduced to 7.7 nm with the deposition of tin-oxide nanoparticles (~7 nm in size) film, which may serve as the electron transport layer in a completed PV device. As noted above, a photoactive PV layer of PV2000:PCBM may be coated over the tin-oxide particles, followed by a hole-transport PEDOT:PSS layer. A relatively thick layer of the hole transport material may be coated on top of the active layer to provide sufficient protection from the mechanically abrasive process of screen-printing a silver top electrode.

Although reference is made herein to particular materials, it is appreciated that other materials having similar functional and/or structural properties may be substituted where appropriate, and that a person having ordinary skill in the art would understand how to select such materials and incorporate them into embodiments of the concepts, techniques, and structures set forth herein without deviating from the scope of those teachings.

FIG. 12 is a block diagram of an example computing environment 1200 for implementing embodiments of the present disclosure. The arrangement and number of components in computing environment 1200 is provided for purposes of illustration. Additional arrangements, numbers of components, and other modifications may be made, consistent with the present disclosure.

As shown in FIG. 12, computing environment 1200 may include one or more computing systems 1210, networks 1220, and machines and/or systems 1230. Computing system(s) 1210 may be coupled machine(s) and/or system(s) 1230 via network(s) 1220.

By way of example a computing system 1210 may include one or more computing devices 1310 of FIG. 13. A computing device 1310 may include, for example, a personal computer, desktop computer, laptop computer, server, mobile computer, mobile phone, smart phone, tablet computer, and/or other type of computing device. In some embodiments, a computing device 1310 may be implemented with hardware devices and/or software applications running thereon. A computing device 1310 may communicate with one or more machine(s) and/or system(s) 1230 (see, e.g., FIGS. 5, 7, 8, 9H) over one or more networks 1220. A computing device 1210 may store software that enables the computing device 1210 to access stored information and to control machine(s) and/or system(s) 1230 to carry out the methods of FIGS. 1, 3, 6, and/or 9H.

Computing environment 1200 may include one or more networks 1220. In some embodiments, network(s) 1220 may be one or more local area networks (LANs), wide area networks (WANs), or any combination of these networks. Network(s) 1220 may include network types such as Ethernet, intranet, twisted-pair, coaxial cable, fiber optic, cellular, satellite, IEEE 802.11, WiFi, terrestrial, Internet, and/or other types of wired or wireless networks. Network(s) 1220 may include any combination of these different network types.

Machines and/or systems 1230 may include one or more machines described with respect to FIG. 8 and/or one or more systems described with respect to FIG. 5, 7, or 9H. In some embodiments, a machine and/or system 1230 may include one or more computing devices (see, e.g., computing devices 1310 of FIG. 13). Computing device(s) 1310 within a machine and/or system 1230 may enable the machine and/or system 1230 to receive instructions from one or more computing systems 1210 over one or more networks 1220. In this manner, a machine and/or system 1230 may be configured to receive instructions for performing portions of the methods described with respect to FIG. 1, 3, 6, or 9H, and to carry out those instructions.

FIG. 13 is a block diagram illustrating an example computing system 1210 that may be used for implementing embodiments consistent with the present disclosure. Computing system 1210 may include one or more computing devices 1310. Computing system 1210 may be used to implement computing system 1210 of FIG. 12 and/or machine(s) and/or system(s) 1230 of FIG. 12. The arrangement and number of components in computing system 1210 is provided for purposes of illustration. Additional arrangements, numbers of components, or other modifications may be made, consistent with the present disclosure.

As shown in FIG. 13, a computing device 1310 may include one or more processors 1320 for executing instructions. Processors suitable for the execution of instructions may include, by way of example, both general and special purpose microprocessors, and any one or more processors of any kind of digital computer. A computing device 1310 may also include one or more input/output (I/O) devices 1330. By way of example, I/O devices 1330 may include keys, buttons, mice, joysticks, styluses, etc. Keys and/or buttons may be physical and/or virtual (e.g., provided on a touch screen interface). A computing device 1310 may also be connected to one or more displays (not shown) via I/O 1330. A display may be implemented using one or more display panels, which may include, for example, one or more cathode ray tube (CRT) displays, liquid crystal displays (LCDs), plasma displays, light emitting diode (LED) displays, touch screen type displays, projector displays (e.g., images projected on a screen or surface, holographic images, etc.), organic light emitting diode (OLED) displays, 3-dimensional (3-D) displays, electronic paper (e-ink) displays, or any combination of the above types of displays.

A computing device 1310 may include one or more storage devices configured to store data and/or software instructions used by processor(s) 1320 to perform operations consistent with disclosed embodiments. For example, a computing device 1310 may include main memory 1340 configured to store one or more software programs that, when executed by processor(s) 1320, cause processor(s) 1320 to perform functions or operations consistent with disclosed embodiments.

By way of example, main memory 1340 may include NOR and/or NAND flash memory devices, read only memory (ROM) devices, random access memory (RAM) devices, etc. A computing device 1310 may also include one or more storage mediums 1350. By way of example, storage medium(s) 1350 may include hard drives, solid state drives, tape drives, redundant array of independent disks (RAID) arrays, etc. Although FIG. 13 illustrates only one main memory 1340 and one storage medium 1350, a computing device 1310 may include any number of main memories 1340 and storage mediums 1350. Further, although FIG. 13 illustrates main memory 1340 and storage medium 1350 as part of computing device 1310, main memory 1340 and/or storage medium 1350 may be located remotely and computing device 1310 may be able to access main memory 1340 and/or storage medium 1350 via network(s) 1220.

Storage medium(s) 1350 may be configured to store data and may store data received from one or more other computing devices 1310. The data may take various forms such as documents, tables, lists, software applications, files, instructions, and any other type of information and/or content that may be used in network applications, or any combination thereof.

A computing device 1310 may further include one or more communication interfaces 1360. Communication interface(s) 1360 may allow software and/or data to be transferred between computing devices 1310, such as between computing system 1210 and machine(s) and/or system(s) 1230 over network(s) 1220. Examples of communication interface 1360 may include a modem, network interface card (e.g., Ethernet card), communications port, personal computer memory international association (PCMCIA) slots and cards, antennas, etc. Communications interface(s) 1360 may transfer software and/or data in the form of signals, which may be electronic, electromagnetic, optical, and/or other types of signals. The signals may be provided to/from communication interface(s) 1360 via a communication path (e.g., network(s) 1220), which may be implemented using wired, wireless, cable, fiber optic, radio frequency (RF), and/or other communications channels.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal, “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

1. A method, comprising:
forming a releasable substrate on a release liner carrier by applying a solution to the release liner carrier; and
forming an electronic device over the releasable substrate to produce a transferable electronic device.

2. The method of claim 1, wherein the solution includes a soluble resin.

3. The method of claim 2, wherein the soluble resin is a polyester.

4. The method of claim 1, wherein the release liner carrier includes a silicone coating.

5. The method of claim 1, further comprising:
identifying a characteristic for the releasable substrate;
choosing a solution based on the identified characteristic; and
applying the chosen solution to the release liner carrier to create a releasable substrate having the identified characteristic.

6. The method of claim 5, wherein the desired characteristic is an ultraviolet light filtering characteristic, further comprising:
determining a concentration of an ultraviolet light filtering dye to include in the solution based on the ultraviolet light filtering characteristic;
choosing a solution that includes the determined concentration of the ultraviolet light filtering dye; and
applying the chosen solution to form the releasable substrate having the ultraviolet light filtering characteristic.

7. The method of claim 5, wherein the desired characteristic is a thickness characteristic, further comprising:
determining a concentration of a soluble resin to include in the solution based on the thickness characteristic;
choosing a solution that includes the determined concentration of the soluble resin; and
applying the chosen solution to form the releasable substrate having the thickness characteristic.

8. The method of claim 1, wherein forming the electronic device further comprises:
forming a first functional layer of the electronic device by coating or printing a first solution on the releasable substrate; and
forming a second functional layer of the electronic device by coating or printing a second solution on the first functional layer.

9. A structure including an electronic device, comprising:
a silicone-coated release liner carrier;
a releasable substrate comprising a resin and formed over the silicone-coated release liner carrier; and
an electronic device that is formed over the releasable substrate.

10. The structure of claim 9, wherein the releasable substrate is a polyester.

11. The structure of claim 9, wherein the release liner carrier is configured to be removed from the releasable substrate without damaging the releasable substrate or the electronic device.

12. The structure of claim 9, wherein the electronic device is a photovoltaic device.

13. The structure of claim 9, wherein the electronic device is composed of at least a first functional layer and a second functional layer, the first functional layer being attached to the releasable substrate.

14. The structure of claim 9, wherein the releasable substrate has an ultraviolet filtering, moisture barrier, scratch resistance, anti-reflectance, or thickness characteristic.

15. The structure of claim 9, wherein the silicone-coated release liner carrier is flexible.

16. A method comprising:
removing a silicone-coated release liner carrier from a releasable substrate comprising a resin, wherein the releasable substrate is attached to an electronic device; and
applying the releasable substrate and electronic device to a permanent substrate.

17. The method of claim 16, further comprising reusing the silicone-coated release liner carrier to form another electronic device.

18. The method of claim 16, wherein the permanent substrate is a fabric.

19. The method of claim 16, wherein the releasable substrate is formed of a polyester.

20. The method of claim 16, further comprising operating the electronic device on the permanent substrate.
